(19) United States
(12) Patent Application Publication
(10) Pub. No.: US 2026/0150548 A1
(43) Pub. Date: May 28, 2026

(54) DISPLAY APPARATUS

(71) Applicant: LG Display Co., Ltd., Seoul (KR)

(72) Inventors: Heetae LIM, Paju-si (KR); Kyunhwang KIM, Paju-si (KR); Hyunsu KWON, Paju-si (KR); Heechul AN, Paju-si (KR); Ohseob KWON, Paju-si (KR); Kiyeong YOON, Paju-si (KR)

(73) Assignee: LG Display Co., Ltd., Seoul (KR)

(21) Appl. No.: 19/305,053

(22) Filed: Aug. 20, 2025

(30) Foreign Application Priority Data
Nov. 26, 2024 (KR) 10-2024-0170681

(51) Int. Cl. H10K 59/65; H10K 59/122; H10K 59/131; H10K 59/80

(52) U.S. Cl. CPC H10K 59/65; H10K 59/122; H10K 59/131; H10K 59/80521; H10K 59/873

(57) ABSTRACT

A display apparatus according to one or more examples includes a substrate, an optical area that includes a transmissive area and a non-transmissive area having different light transmittances and displays a screen, a thin film transistor disposed on the substrate, a protective layer disposed on the thin film transistor, a light-emitting part disposed on the protective layer, and a transparent and magnetic close-contact member disposed on the protective layer, in which the light-emitting part is disposed in the non-transmissive area, and the close-contact member is disposed in the transmissive area.

### CROSS-REFERENCE TO RELATED APPLICATIONS

The present application claims the benefit of and priority to Korean Patent Application No. 10-2024-0170681, filed Nov. 26, 2024, the entire contents of which are incorporated herein by reference for all purposes.

### BACKGROUND

### 1. Technical Field

The present disclosure relates to a display apparatus.

### 2. Description of Related Art

As the information society develops, various demands for display apparatuses for displaying images are increasing, and various types of display apparatuses, such as a liquid crystal display (LCD) apparatus and an organic light emitting diode (OLED) display apparatus, are being utilized.

Among the display apparatuses, there is an advantage in that the OLED display apparatus as the self-luminous type has a wider viewing angle and a higher contrast ratio, and can be lighter and thinner and has lower power consumption than the LCD apparatus because it does not require a separate backlight. In addition, there is an advantage in that the OLED display apparatus can drive at a low voltage, have a fast response time, and especially have the inexpensive manufacturing cost.

The description of related art should not be considered prior art merely because it is mentioned in or associated with this section. The description of related art includes information that describes one or more aspects of the subject technology, and the description in this section does not limit the scope of the invention.

### SUMMARY

One or more aspects of the present disclosure are directed to providing a display apparatus with which a fine meta mask (FMM) can be in close contact.

One or more aspects of the present disclosure are also directed to providing a display apparatus in which it is possible to suppress or prevent a deposition defect of a display panel through close-contact of an FMM.

One or more aspects of the present disclosure are also directed to providing a display apparatus in which it is possible to minimize a spot defect (e.g., shadow or shadow mura) of a display panel.

Aspects of the present disclosure are not limited to the above-described aspects, and other technical aspects may be inferred from the following embodiments.

According to one embodiment of the present disclosure, there is provided a display apparatus including a substrate, an optical area including a transmissive area and a non-transmissive area having different light transmittances and for displaying, a thin film transistor disposed on the substrate, a protective layer disposed on the thin film transistor, a light-emitting part disposed on the protective layer, and a transparent and magnetic close-contact member disposed on the protective layer, wherein the light-emitting part is disposed in the non-transmissive area, and the transparent and magnetic close-contact member is disposed in the transmissive area.

According to one embodiment of the present disclosure, there is provided a display apparatus including a display area for displaying a screen, a non-display area disposed outside the display area, an optical area including a transmissive area and a non-transmissive area having different light transmittances, a normal area having a higher pixels per inch (PPI) than the optical area, a light-emitting part disposed across the non-transmissive area of the optical area and the normal area, a transparent and magnetic close-contact member disposed in the transmissive area, and an optical electronic device that is disposed to overlap the optical area and to receive external light.

Detailed matters of other embodiments are included in the detailed description and accompanying drawings.

According to the embodiments of the present disclosure, it is possible to provide the display apparatus with which the fine meta mask (FMM) can be in close contact.

According to the embodiments of the present disclosure, it is possible to suppress or prevent a deposition defect of the display panel through the close-contact of the FMM.

According to the embodiments of the present disclosure, it is possible to minimize a spot defect (e.g., shadow or shadow mura) of the display panel.

According to the embodiments of the present disclosure, it is possible to suppress or prevent the spot defect phenomenon of the display panel, thereby enabling operation defect prevention, luminance improvement, etc. of the display apparatus and reducing power consumption.

However, effects obtainable from the present disclosure are not limited to the above-described effects, and other effects that are not mentioned will be able to be clearly understood by those skilled in the art to which the present disclosure pertains based on the following description.

Additional features, advantages, and aspects of the present disclosure are set forth in part in the description that follows and in part will become apparent from the present disclosure or may be learned by practice of the inventive concepts provided herein. Other features, advantages, and aspects of the present disclosure may be realized and attained by the descriptions provided in the present disclosure, or derivable therefrom, and the claims hereof as well as the drawings. It is intended that all such features, advantages, and aspects be included within this description, be within the scope of the present disclosure, and be protected by the following claims. Nothing in this section should be taken as a limitation on those claims. Further features, advantages, and aspects are discussed below in conjunction with embodiments of the present disclosure.

It is to be understood that both the foregoing description and the following description of the present disclosure are examples, and are intended to provide further explanation of the disclosure as claimed.

### BRIEF DESCRIPTION OF THE DRAWINGS

The accompanying drawings, which are included to provide a further understanding of the present disclosure, are incorporated in and constitute a part of this present disclosure, illustrate aspects and embodiments of the present disclosure, and together with the description serve to explain principles and examples of the disclosure.

FIGS. 1 to 4 are schematic plan views of a display apparatus according to one embodiment.

FIG. 5 is a plan view of a normal area of a display area according to one embodiment.

FIG. 6 is a cross-sectional view along line A-A′ in FIG. 5.

FIG. 7 is a specific cross-sectional view of a light-emitting part of FIG. 6.

FIG. 8 is a specific cross-sectional view of a light-emitting part according to a modified example.

FIG. 9 is a cross-sectional view of a touch part according to FIG. 6.

FIG. 10 is a plan view of a first optical area of the display area according to one embodiment.

FIG. 11 is a cross-sectional view along line B-B′ in FIG. 10.

FIG. 12 is a schematic view illustrating a process of forming an organic layer by a deposition mask.

FIG. 13 is a view illustrating a cross section of a first optical area according to another embodiment.

FIG. 14 is a specific cross-sectional view of a light-emitting part of FIG. 13.

FIG. 15 is a specific cross-sectional view of a light-emitting part according to a modified example of FIG. 14.

FIG. 16 is a plan view of a deposition mask for depositing an organic layer of a display panel of FIG. 13.

FIG. 17 is an enlarged view of a first mask area and a second mask area of the deposition mask of FIG. 16.

FIG. 18 is a schematic view illustrating a process of forming an organic layer by the deposition mask of FIG. 16.

FIG. 19 is a schematic plan view of a display apparatus according to another embodiment.

FIG. 20 is an enlarged view of area Q1 in FIG. 19.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and/or convenience.

### DETAILED DESCRIPTION

Hereinafter, embodiments will be described with reference to the accompanying drawings. In the specification, when a first component (or an area, a layer, a portion, etc.) is described as “on,” “connected,” or “coupled to” a second component, it means that the first component may be directly connected/coupled to the second component or a third component may be disposed therebetween.

The same reference numerals indicate the same components. In addition, in the drawings, thicknesses, proportions, and dimensions of components are exaggerated for effective description of technical contents. The term “and/or” includes all one or more combinations that may be defined by the associated configurations.

Terms such as first and second may be used to describe various components, but the components are not limited by the terms. The terms are used only for the purpose of distinguishing one component from another. For example, a first component may be referred to as a second component, and similarly, the second component may also be referred to as the first component without departing from the scopes of the embodiments. The singular includes the plural unless the context clearly dictates otherwise. For example, an element may be one or more elements. An element may include a plurality of elements. The word “exemplary” is used to mean serving as an example or illustration. Embodiments are example embodiments. Aspects are example aspects. In one or more implementations, “embodiments,” “examples,” “aspects,” and the like should not be construed to be preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.”

Terms such as “under,” “at a lower side,” “above,” and “at an upper side” are used to describe the relationship between the components illustrated in the drawings. The terms are relative concepts and are described with respect to directions marked in the drawings.

It should be understood that term such as “includes” or “has” is intended to specify the presence of features, numbers, steps, operations, components, parts, or a combination thereof described in the specification and does not preclude the presence or addition possibility of one or more other features, numbers, steps, operations, components, parts, or combinations thereof in advance.

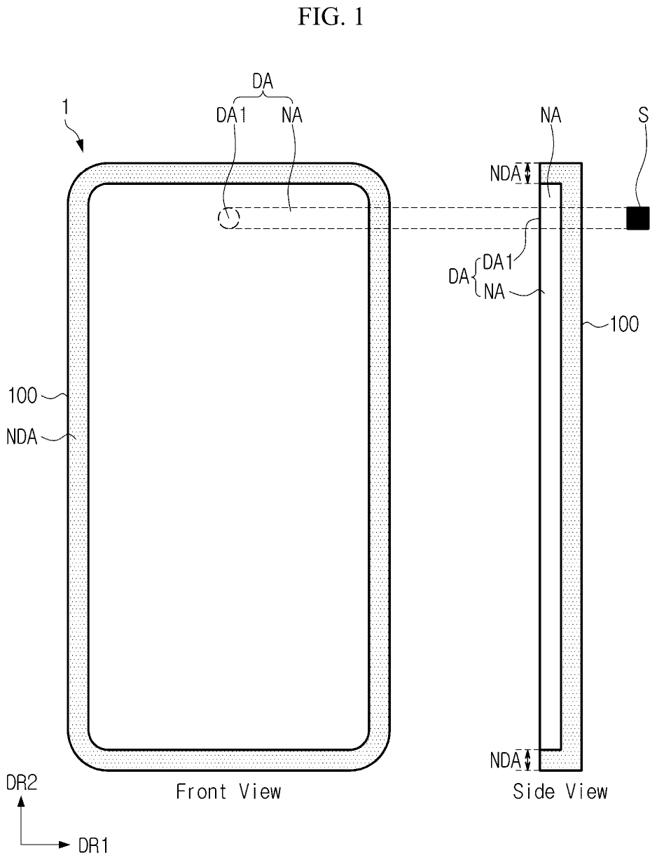

FIGS. 1 to 4 are schematic plan views of a display apparatus according to one embodiment.

Referring to FIGS. 1 to 4, a display apparatus 1 according to one embodiment of the present disclosure may include a display panel 100 for displaying an image and one or more optical electronic devices S, S1, and S2. The optical electronic devices S, S1, and S2 may include an electronic device (or a light-receiving device) for receiving light, such as a camera or a sensor.

The display panel 100 may include a display area DA and a non-display area NDA disposed around the display area DA. The display area DA is an area in which an image is displayed on the display panel 100. A plurality of sub-pixels forming a plurality of pixels and a circuit for driving the plurality of sub-pixels may be disposed in the display area DA.

The display area DA may include at least one of a normal area NA, a first optical area DA1, and a second optical area DA2, but is not limited thereto.

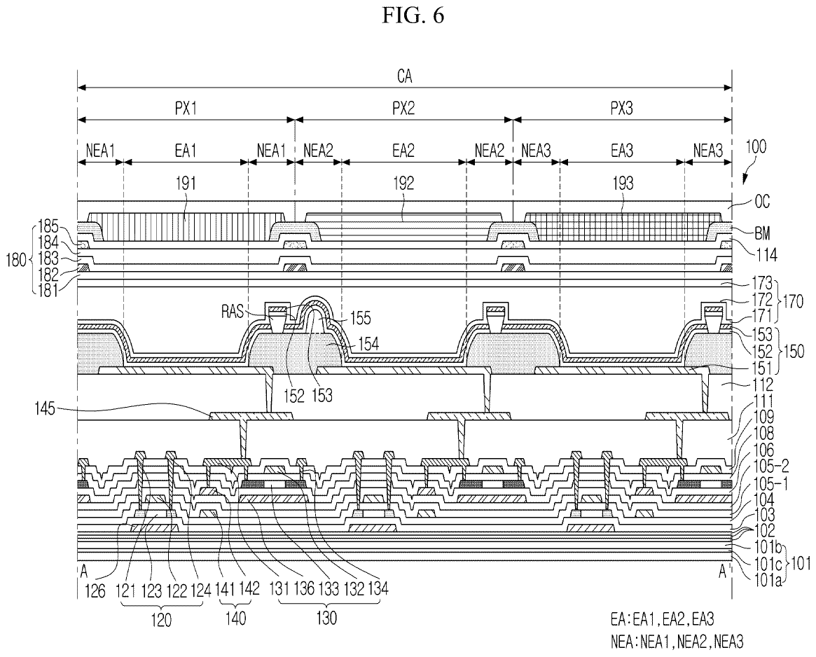

The normal area NA, the first optical area DA1, and the second optical area DA2 may be defined on a substrate 101 (see FIG. 6).

The flat surface shape of the display area DA may have a rectangular shape. However, the embodiments of the present disclosure are not limited thereto, and the flat surface shape of the display area DA may be a square, circular, elliptical, or other polygonal shapes. For example, the display area DA may have a rectangular shape with rounded corners, but is not limited thereto and may also have a rectangular shape with angled corners.

In embodiments, a first direction DR1 and a second direction DR2 are different directions and intersect each other, for example, directions that intersect vertically in a plan view. In FIG. 1, the first direction DR1 may be generally the same as an extension direction of short sides of the display panel 100, and the second direction DR2 may be the same as an extension direction of long sides of the display panel 100. However, the directions described in the embodiments should be understood as indicating relative directions, and the embodiments are not limited to the described directions.

The display area DA may include short sides extending in the first direction DR1 and long sides extending in the second direction DR2.

The non-display area NDA may surround the display area DA, but is not limited thereto. The non-display area NDA may be disposed at one side and the other side of the display area DA in the first direction DR1 and one side and the other side of the display area DA in the second direction DR2.

The non-display area NDA is an area in which a screen is not displayed and may define a bezel area.

In FIGS. 1 to 4, the one or more optical electronic devices S, S1, and S2 are electronic components located below (a side opposite to a viewing surface) the display panel 100.

Light may enter a front surface (a viewing surface) of the display panel 100, transmit the display panel 100, and may be transferred to the one or more optical electronic devices S, S1, and S2 located below (the side opposite to the viewing surface) the display panel 100.

The one or more optical electronic devices S, S1, and S2 may be devices for receiving light that has transmitted the display panel 100 and performing a predetermined function according to the received light.

For example, the optical electronic devices S, S1, and S2 may include one or more of a camera or a proximity sensor.

As described above, the optical electronic devices S, S1, and S2 are devices that require light reception, but may be located below the display panel 100. That is, the optical electronic devices S, S1, and S2 may be located at the side opposite to the viewing surface of the display panel 100. The optical electronic devices S, S1, and S2 are not exposed to the front of the display apparatus 1. Accordingly, when a user views the front surface of the display apparatus 1, the optical electronic devices S, S1, and S2 are not visible.

For example, the camera located below the display panel 100 is a front camera for capturing a forward image and may be viewed as a camera lens.

The optical electronic devices S, S1, and S2 may be disposed to overlap the display area DA of the display panel 100. That is, the optical electronic devices S, S1, and S2 may be located in the display area DA.

Referring to FIGS. 1 to 4, the display area DA may include the normal area NA and the one or more optical areas DA1 and DA2. Both the normal area NA and the one or more optical areas DA1 and DA2 may be areas in which the screen is displayed. The one or more optical areas DA1 and DA2 may be areas that overlap the one or more optical electronic devices S, S1, and S2.

According to the example of FIG. 1, the display area DA may include the normal area NA and a first optical area DA1. Here, at least a part of the first optical area DA1 may overlap the optical electronic device S. FIG. 1 illustrates the first optical area DA1 having a circular structure, but the shape of the first optical area DA1 according to one embodiment is not limited thereto.

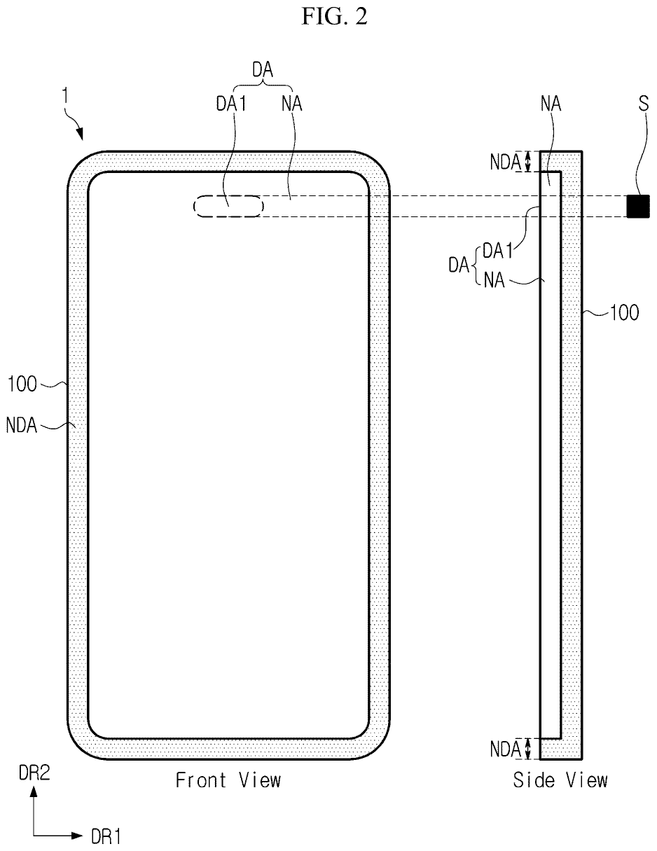

For example, as illustrated in FIG. 2, the shape of the first optical area DA1 may be an octagon and may also be formed in various polygonal shapes.

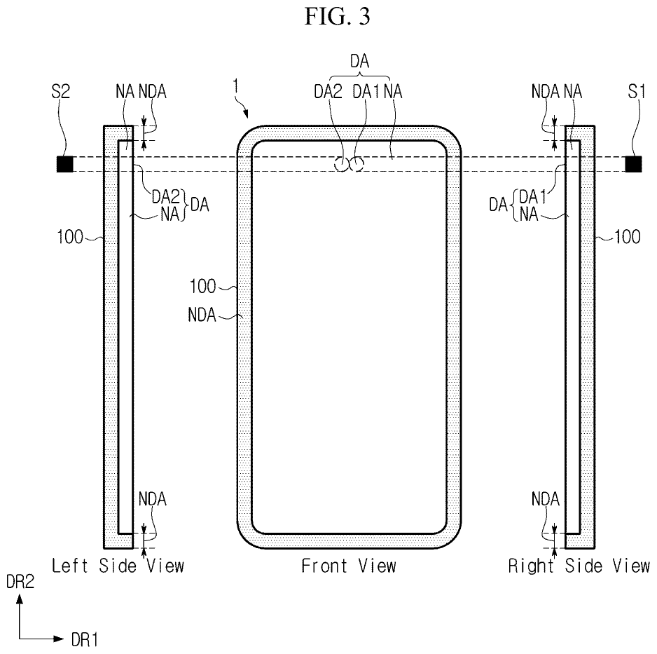

According to the example of FIG. 3, the display area DA may include the normal area NA, the first optical area DA1, and the second optical area DA2. In the example of FIG. 3, the normal area NA may be present between the first optical area DA1 and the second optical area DA2. Here, at least a part of the first optical area DA1 may overlap the first optical electronic device S1, and at least a part of the second optical area DA2 may overlap the second optical electronic device S2.

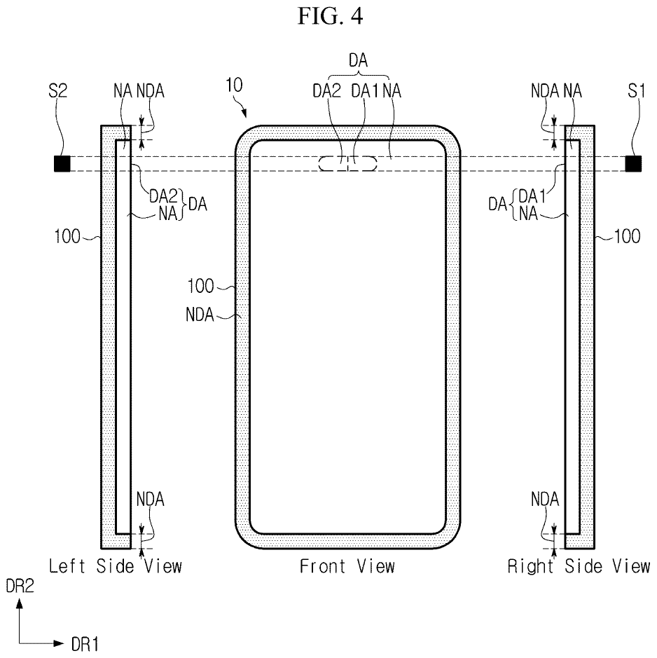

According to the example of FIG. 4, the display area DA may include the normal area NA, the first optical area DA1, and the second optical area DA2. In the example of FIG. 4, the normal area NA is not present between the first optical area DA1 and the second optical area DA2. That is, the first optical area DA1 may come into contact with the second optical area D2. Here, at least a part of the first optical area DA1 may overlap the first optical electronic device S1, and at least a part of the second optical area DA2 may overlap the second optical electronic device S2.

Both an image display structure and a light-transmitting structure need to be formed in the one or more optical areas DA1 and DA2. That is, since the one or more optical areas DA1 and DA2 are parts of the display area DA, sub-pixels for image display need to be disposed in the one or more optical areas DA1 and DA2. A light-transmitting structure for transmitting light to the one or more optical electronic devices S, S1, and S2 needs to be formed in the one or more optical areas DA1 and DA2.

The one or more optical electronic devices S, S1, and S2 are devices that require light reception, but are located behind (below, the side opposite to the viewing surface) the display panel 100 to receive light that has transmitted the display panel 100.

The one or more optical electronic devices S, S1, and S2 are not exposed to the front surface (the viewing surface) of the display panel 100. Accordingly, when a user views the front surface of the display apparatus 1, the optical electronic devices S, S1, and S2 are not visible to the user.

For example, the first optical electronic device S and S1 may be a camera, and the second optical electronic device S2 may be a detection sensor, such as a proximity sensor, an illuminance sensor, etc. For example, the detection sensor may be an infrared sensor for detecting infrared rays.

Conversely, the first optical electronic device S1 may be a detection sensor, and the second optical electronic device S2 may be a camera.

Hereinafter, for convenience of description, an example in which the first optical electronic device S and S1 is a camera and the second optical electronic device S2 is a detection sensor will be described. Here, the camera may be a camera lens or an image sensor.

When the first optical electronic device S and S1 is a camera, the camera is located behind (below) the display panel 100, but may be a front camera for capturing a forward image of the display panel 100. Accordingly, the user may capture an image through a camera that is not visible on the viewing surface while looking at the viewing surface of the display panel 100.

The normal area NA and the one or more optical areas DA1 and DA2 that are included in the display area DA are areas in which an image may be displayed, but the normal area NA is an area in which a light-transmitting structure does not need to be formed, and the one or more optical areas DA1 and DA2 are areas in which the light-transmitting structure needs to be formed.

Accordingly, the one or more optical areas DA1 and DA2 need to have a transmittance of a predetermined level or more, and the normal area NA may not have the light-transmitting property or may have a low transmittance less than the predetermined level.

For example, the one or more optical areas DA1 and DA2 may differ from the normal area NA in terms of a resolution, a sub-pixel arrangement structure, the number of sub-pixels per unit area, an electrode structure, a line structure, an electrode arrangement structure, a line arrangement structure, etc.

For example, the number of sub-pixels per unit area in the one or more optical areas DA1 and DA2 may be less than the number of sub-pixels per unit area in the normal area NA. That is, resolutions of the one or more optical areas DA1 and DA2 may be lower than a resolution of the normal area NA. In this case, the number of sub-pixels per unit area is a unit for measuring a resolution and may be referred to as pixels per inch (PPI) that refers to the number of pixels in 1 inch.

For example, the number of sub-pixels per unit area in the first optical area DA1 may be less than the number of sub-pixels per unit area in the normal area NA. The number of sub-pixels per unit area in the second optical area DA2 may be more than or equal to the number of sub-pixels per unit area in the first optical area DA1.

The first optical area DA1 may have various shapes, such as a circle, an ellipse, a square, a hexagon, an octagon, etc. The second optical area DA2 may have various shapes, such as a circle, an ellipse, a square, a hexagon, an octagon, etc. The first optical area DA1 and the second optical area DA2 may have the same shape or different shapes.

Referring to FIG. 3, when the first optical area DA1 comes into contact with the second optical area DA2, the entire optical area including the first optical area DA1 and the second optical area DA2 may also have various shapes, such as a circle, an ellipse, a square, a hexagon, an octagon, etc.

Hereinafter, for convenience of description, an example in which each of the first optical area DA1 and the second optical area DA2 is circular will be described.

In the display apparatus 1 according to one embodiment, when the first optical electronic devices S and S1 that are not exposed to the outside and are hidden below the display panel 100 are infrared sensors (or near-infrared sensors), the display apparatus 1 according to one embodiment may be referred to as a display to which a under display IR (UDIR) sensor technology is applied.

Accordingly, in the case of the display apparatus 1 according to one embodiment, since a notch or camera hole for camera exposure does not need to be formed in the display panel 100, an area of the display area DA is not reduced.

Accordingly, since the notch or camera hole for camera exposure does not need to be formed in the display panel 100, the size of the bezel area can be reduced, and since design restrictions are eliminated, the degree of freedom related to a design can be increased.

In a display apparatus 1 according to one embodiment, even though the one or more optical electronic devices S, S1, and S2 are located to be hidden behind the display panel 100, the one or more optical electronic devices S, S1, and S2 need to normally receive light and perform a predetermined function normally.

In addition, in the display apparatus 1 according to one embodiment, even though the one or more optical electronic devices S, S1, and S2 are located to be hidden behind the display panel 100 and overlap the display area DA, a normal image needs to be displayed in the one or more optical areas DA1 and DA2 overlapping the one or more optical electronic devices S, S1, and S2 in the display area DA.

Accordingly, the display apparatus 1 according to one embodiment of the present disclosure may have a structure capable of increasing the transmittances of the first optical area DA1 and the second optical area DA2 that overlap the optical electronic devices S, S1, and S2.

Hereinafter, the embodiment of FIG. 1 among the embodiments of FIGS. 1 to 4 will be mainly described, but the description of the normal area NA of FIG. 1 may be applied to the normal area NA of FIGS. 2 to 4 in the substantially the same manner, and the description of the first optical area DA1 of FIG. 1 may also be applied to the optical areas DA1 and DA2 of FIGS. 2 to 4 in the substantially the same manner.

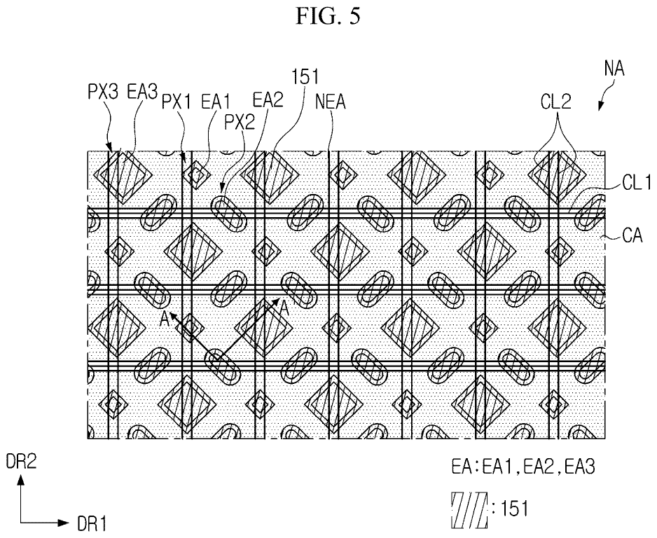

FIG. 5 is a plan view of a normal area of a display area according to one embodiment. FIG. 6 is a cross-sectional view along line A-A′ in FIG. 5.

FIG. 5 illustrates an arrangement of sub-pixels PX1, PX2, and PX3 of a normal area NA of the display area DA according to one embodiment. FIG. 6 illustrates a cross-sectional structure of each sub-pixel PX1, PX2, or PX3 in the normal area NA.

Referring to FIGS. 1, 5, and 6, a plurality of sub-pixels PX may be disposed in the normal area NA. The plurality of sub-pixels PX1, PX2, and PX3 may include a first sub-pixel PX1, a second sub-pixel PX2, and a third sub-pixel PX3.

For example, the plurality of sub-pixels may include a red sub-pixel (Red SP) (or the first sub-pixel PX1) that emits red light, a green sub-pixel (Green SP) (or the second sub-pixel PX2) that emits green light, and a blue sub-pixel (Blue SP) (or the third sub-pixel PX3) that emits blue light. FIG. 5 illustrates the flat surface shapes of the plurality of sub-pixels PX1, PX2, and PX3 are a square or an oval, but the embodiments of the present disclosure are not limited thereto, and the flat surface shapes of the plurality of sub-pixels PX1, PX2, and PX3 may be circular.

Accordingly, the normal area NA may include a light-emitting area EA. The light-emitting area EA may include a plurality of light-emitting areas EA1, EA2, and EA3. The light-emitting areas EA1, EA2, and EA3 may be disposed in the sub-pixels PX1, PX2, and PX3, respectively. That is, the first sub-pixel PX1 may include a first light-emitting area EA1, the second sub-pixel PX2 may include a second light-emitting area EA2, and the third sub-pixel PX3 may include a third light-emitting area EA3.

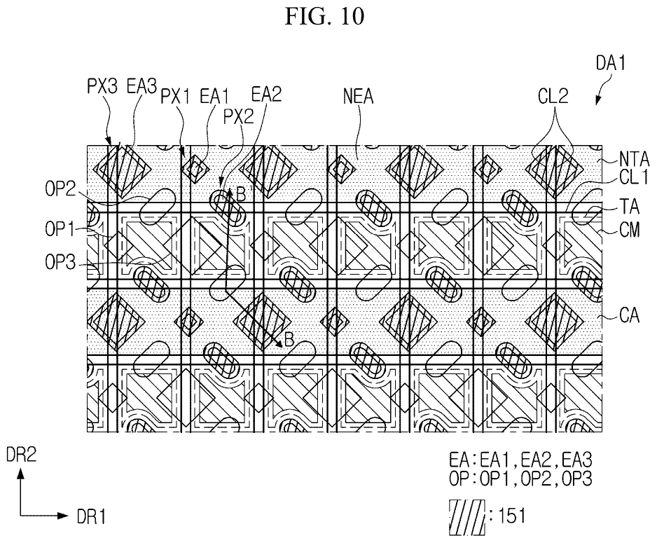

The normal area NA may not include a transmissive area TA (see FIG. 10) to be described below.

A pixel PX (see FIG. 1) of the display panel 100 may include a plurality of sub-pixels PX1, PX2, and PX3. The first sub-pixel PX1 may be a red sub-pixel, the second sub-pixel PX2 may be a green sub-pixel, and the third sub pixel PX3 may be a blue sub-pixel, but the embodiments of the present disclosure are not limited thereto. In some embodiments, the pixel PX further includes a fourth sub-pixel, and the fourth sub-pixel may be a white sub-pixel, but the embodiments of the present disclosure are not limited thereto. In some embodiments, the pixel may include one red sub-pixel, two green sub-pixels, and one blue sub-pixel, but the embodiments of the present disclosure are not limited thereto. For example, the plurality of sub-pixels PX1, PX2, and PX3 may be arranged in a stripe manner in the first direction DR1, but are not limited thereto, and may be arranged in a pentile manner.

The display apparatus 1 may include circuit lines CL1 and CL2 connected to each of the sub-pixels PX1, PX2, and PX3. Each of a first circuit line CL1 and a second circuit line CL2 may be provided as a plurality of circuit lines.

Each of the plurality of first circuit line CL1 may extend in the first direction DR1 and may be repeatedly disposed in the second direction DR2. Each of the plurality of second circuit lines CL2 may extend in the second direction DR2 and may be repeatedly disposed in the first direction DR1.

At least parts of the first circuit line CL1 and the second circuit line CL2 may be disposed in the display area DA.

The first circuit line CL1 and the second circuit line CL2 may transmit electrical signals required for driving each of the sub-pixels PX1, PX2, and PX3 to each of the sub-pixels PX1, PX2, and PX3. Each of the first circuit line CL1 and the second circuit line CL2 may include lines capable of transmitting the electrical signals required for driving each of the sub-pixels PX1, PX2, and PX3.

For example, but the embodiments of the present disclosure are not limited thereto, the first circuit line CL1 may include a gate line electrically connected to a gate driving circuit, etc., and the second circuit line CL2 may include a data line electrically connected to a data driving circuit, etc.

In the cross-sectional view of FIG. 6, a separate second circuit line CL2 is not illustrated, but the second circuit line CL2 may correspond to one of components of a first thin film transistor 120, a second thin film transistor 130, and a storage capacitor 140 or correspond to a line electrically connected to at least one of the first thin film transistor 120, the second thin film transistor 130, and the storage capacitor 140.

The display panel 100 may include the substrate 101, the first thin film transistor 120, the second thin film transistor 130, the storage capacitor 140, a light-emitting part 150, an encapsulation part 170, a touch part 180, a filter insulating layer 114, a black matrix BM, color filters 191, 192, and 193, and a planarization layer OC.

The display panel 100 may include at least one panel insulating layer and at least one touch insulating layer between the substrate 101 and the light-emitting part 150. The at least one panel insulating layer may include at least one of a buffer layer 102, a first insulating layer 103, a second insulating layer 104, a 3-1 insulating layer 105-1, a 3-2 insulating layer 105-2, a fourth insulating layer 106, a fifth insulating layer 108, a sixth insulating layer 109, a first protective layer 111, and a second protective layer 112, and the at least one touch insulating layer may include at least one of a touch buffer layer 181, a first touch insulating layer 183, and a second touch insulating layer 184.

The substrate 101 may include one or more plastic materials. For example, the substrate 101 may be a multi-substrate including a plurality of plastic materials, such as polyimide, etc. For example, the substrate 101 may include a first substrate portion 101a and a second substrate portion 101b each including a plastic material, and a third substrate portion 101c including an inorganic insulation material between the first substrate portion 101a and the second substrate portion 101b, but the embodiments of the present disclosure are not limited thereto.

The display apparatus 1 may further include a circuit area CA. The circuit area CA may be disposed on the substrate 101. The circuit area CA may be defined by the substrate 101. Components for driving the light-emitting part 150 may be disposed in the circuit area CA. For example, the first thin film transistor 120, the second thin film transistor 130, the storage capacitor 140, and lines connected thereto may be disposed in the circuit area CA.

A buffer layer 102 may be disposed on the substrate 101. The buffer layer 102 can minimize or delay the diffusion of moisture or oxygen penetrating the substrate 101. The buffer layer 102 may be formed by alternately stacking silicon nitride (SiNₓ) and silicon oxide (SiOₓ) at least once, but the embodiments of the present disclosure are not limited thereto.

A first light-blocking layer 126 may be disposed on the buffer layer 102. The first light-blocking layer 126 can prevent light from transmitting a first semiconductor layer 123 of the first thin film transistor 120. For example, the first semiconductor layer 123 may be disposed to overlap the first light-blocking layer 126. The first light-blocking layer 126 may be formed of a single layer or multiple layers formed of one of molybdenum (Mo), aluminum (Al), chromium (Cr), nickel (Ni), neodymium (Nd), and copper (Cu) or an alloy thereof, but the embodiments of the present disclosure are not limited thereto.

The first insulating layer 103 may be disposed on the buffer layer 102 and the first light-blocking layer 126. The first insulating layer 103 can prevent a short circuit between a component of the first thin film transistor 120 and the first light-blocking layer 126. The first insulating layer 103 may be formed of the same material as the buffer layer 102, but the embodiments of the present disclosure are not limited thereto. For example, the first insulating layer 103 may be formed of an inorganic insulation material, such as silicon nitride (SiNₓ) or silicon oxide (SiOₓ), but the embodiments of the present disclosure are not limited thereto.

The first thin film transistor 120 may be disposed on the first insulating layer 103. The first thin film transistor 120 may include a first source electrode 121, a first gate electrode 122, the first semiconductor layer 123, and a first drain electrode 124.

The first semiconductor layer 123 may be disposed on the first insulating layer 103. The first semiconductor layer 123 may include a metal oxide semiconductor, such as indium-gallium-zinc oxide (IGZO), and a silicon-based semiconductor material, such as amorphous silicon, polycrystalline silicon, etc., but the embodiments of the present disclosure are not limited thereto. The first semiconductor layer 123 may include a channel area, a source area, and a drain area.

Since the polycrystalline semiconductor layer has higher mobility than the amorphous semiconductor layer and the oxide semiconductor layer, power consumption can be less, and reliability can be excellent. Accordingly, a driving transistor may be formed of the polycrystalline semiconductor layer.

A second insulating layer 104 may be disposed on the first semiconductor layer 123. The second insulating layer 104 may be formed of the same material as the first insulating layer 103 and can prevent a short circuit between the first semiconductor layer 123 and another component of the first thin film transistor 120.

The first gate electrode 122 may be disposed on the second insulating layer 104. The first gate electrode 122 may be disposed on the second insulating layer 104 to overlap the channel area of the first semiconductor layer 123. The first gate electrode 122 may be formed of a single layer or multiple layers formed of molybdenum (Mo), copper (Cu), titanium (Ti), aluminum (Al), chromium (Cr), gold (Au), nickel (Ni), neodymium (Nd), or a compound thereof, but the embodiments of the present disclosure are not limited thereto. The first gate electrode 122 may be disposed along with a gate line.

The third insulating layers 105-1 and 105-2 may be disposed on the first gate electrode 122. The third insulating layers 105-1 and 105-2 may be formed by alternately stacking silicon nitride (SiNₓ) and silicon oxide (SiOₓ) at least once, but the embodiments of the present disclosure are not limited thereto. For example, the 3-1 insulating layer 105-1 may include silicon oxide (SiOₓ), and the 3-2 insulating layer 105-2 may include silicon nitride (SiNₓ), but the embodiments of the present disclosure are not limited thereto.

The first source electrode 121 and the first drain electrode 124 may be disposed on the third insulating layers 105-1 and 105-2.

The first source electrode 121 and the first drain electrode 124 may be electrically connected to the first semiconductor layer 123 through contact holes. The first source electrode 121 and the first drain electrode 124 may be formed of a metallic material. For example, the first source electrode 121 and the first drain electrode 124 may be formed of a single layer or multiple layers formed of one of molybdenum (Mo), aluminum (Al), chromium (Cr), gold (Au), titanium (Ti), nickel (Ni), neodymium (Nd), and copper (Cu) or an alloy thereof, but the embodiments of the present disclosure are not limited thereto.

The first source electrode 121 and the first drain electrode 124 may be disposed along with a data line. For example, the data line may be formed of the same material as the first source electrode 121 and the first drain electrode 124 and formed on the same layer as the first source electrode 121 and the first drain electrode 124, but the embodiments of the present disclosure are not limited thereto.

The storage capacitor 140 may be disposed to be spaced apart from the first thin film transistor 120. The storage capacitor 140 may include a first storage electrode 141 and a second storage electrode 142.

The first storage electrode 141 may be formed of the same material as the first gate electrode 122 and disposed on the same layer as the first gate electrode 122, but the embodiments of the present disclosure are not limited thereto.

The second storage electrode 142 may be disposed on the first storage electrode 141. The second storage electrode 142 may be disposed on the third insulating layers 105-1 and 105-2, and the third insulating layers 105-1 and 105-2 between the first storage electrode 141 and the second storage electrode 142 may be used as a dielectric to generate a capacitance. The second storage electrode 142 may be formed of the same material as the first storage electrode 141, but the embodiments of the present disclosure are not limited thereto.

The second thin film transistor 130 may be disposed to be spaced apart from the first thin film transistor 120 and the storage capacitor 140. The second thin film transistor 130 may include a second source electrode 131, a second gate electrode 132, a second semiconductor layer 133, and a second drain electrode 134.

A second light-blocking layer 136 may be disposed on the same layer as the second storage electrode 142.

The second light-blocking layer 136 can prevent light from traveling to the second semiconductor layer 133 similar to the first light-blocking layer 126, thereby extending the life of the second thin film transistor 130. For example, the second semiconductor layer 133 may be disposed to overlap the second light-blocking layer 136.

The fourth insulating layer 106 may be disposed on the second light-blocking layer 136. The fourth insulating layer 106 may be formed of the same material as the first insulating layer 103, the second insulating layer 104, or the third insulating layers 105-1 and 105-2, but the embodiments of the present disclosure are not limited thereto.

The second semiconductor layer 133 may be disposed on the fourth insulating layer 106. The second semiconductor layer 133 may include a source area, a drain area, and a channel area between the source area and the drain area.

The second semiconductor layer 133 may include a metal oxide semiconductor, such as indium-gallium-zinc oxide (IGZO), and a silicon-based semiconductor material, such as amorphous silicon, polycrystalline silicon, etc., but the embodiments of the present disclosure are not limited thereto.

The fifth insulating layer 108 may be disposed on the second semiconductor layer 133. The fifth insulating layer 108 may be formed of the same material as the first insulating layer 103, the second insulating layer 104, the third insulating layers 105-1 and 105-2, or the fourth insulating layer 106, but the embodiments of the present disclosure are not limited thereto.

The second gate electrode 132 may be disposed on the fifth insulating layer 108.

The second gate electrode 132 may be formed of the same material as the first gate electrode 122. For example, the second gate electrode 132 may be formed of a single layer or multiple layers formed of molybdenum (Mo), copper (Cu), titanium (Ti), aluminum (Al), chromium (Cr), gold (Au), nickel (Ni), neodymium (Nd), or a compound thereof, but the embodiments of the present disclosure are not limited thereto.

The sixth insulating layer 109 may be disposed on the second gate electrode 132. The sixth insulating layer 109 may be formed of the same material as the first insulating layer 103, the second insulating layer 104, the third insulating layers 105-1 and 105-2, the fourth insulating layer 106, or the fifth insulating layer 108, but the embodiments of the present disclosure are not limited thereto.

The first source electrode 121, the first drain electrode 124, the second source electrode 131, and the second drain electrode 134 may be disposed on the sixth insulating layer 109.

The second source electrode 131 and the second drain electrode 134 may be formed of the same material as the first source electrode 121 and the first drain electrode 124 and disposed on the same layer as the first source electrode 121 and the first drain electrode 124, but the embodiments of the present disclosure are not limited thereto. For example, the second source electrode 131 and the second drain electrode 134 may be formed of a single layer or multiple layers formed of any one of molybdenum (Mo), aluminum (Al), chromium (Cr), gold (Au), titanium (Ti), nickel (Ni), neodymium (Nd), and copper (Cu) or an alloy thereof, but the embodiments of the present disclosure are not limited thereto. For example, the second source electrode 131 may be electrically connected to the second storage electrode 142. The second source electrode 131 may pass through the sixth insulating layer 109, the fifth insulating layer 108, and the fourth insulating layer 106 and may be electrically connected to the second storage electrode 142.

The first thin film transistor 120 may be a driving transistor, and the second thin film transistor 130 may be a switching transistor, but the embodiments of the present disclosure are not limited thereto.

A first protective layer 111 may be disposed on the first source electrode 121 and the first drain electrode 124.

The first protective layer 111 may planarize an upper portion of the first thin film transistor 120 and protect the first thin film transistor 120. The first protective layer 111 may be formed of an organic material. For example, the first protective layer 111 may be formed of an organic material including an acrylic resin, an epoxy resin, a phenolic resin, a polyamide resin, or a polyimide resin, but the embodiments of the present disclosure are not limited thereto.

The second protective layer 112 may be disposed on the first protective layer 111. The second protective layer 112 may be formed of the same material as the first protective layer 111, but the embodiments of the present disclosure are not limited thereto.

In some embodiments, a third protective layer may be further disposed on an upper surface of the second protective layer 112, but the embodiments of the present disclosure are not limited thereto.

A connection electrode 145 may be disposed between the first protective layer 111 and the second protective layer 112.

The connection electrode 145 may electrically connect the first thin film transistor 120 to the light-emitting part 150. The connection electrode 145 may be formed of the same material as the first source electrode 121 and the first drain electrode 124, but the embodiments of the present disclosure are not limited thereto.

The connection electrode 145 may be formed of a single layer or multiple layers formed of one of molybdenum (Mo), aluminum (Al), chromium (Cr), gold (Au), titanium (Ti), nickel (Ni), neodymium (Nd), and copper (Cu) or an alloy thereof, but the embodiments of the present disclosure are not limited thereto.

The light-emitting part 150 may be disposed on the second protective layer 112. The light-emitting part 150 may include a first electrode 151, an organic layer 152, and a second electrode 153. The first electrode 151 may serve as an anode, and the second electrode 153 may serve as a cathode.

The first electrode 151 may be disposed on the second protective layer 112. The first electrode 151 may be electrically connected to the first thin film transistor 120 through a contact hole formed in the second protective layer 112. The first electrode 151 may be a reflective electrode that reflects light, but the embodiments of the present disclosure are not limited thereto. The first electrode 151 may include a metallic material with high reflectance, such as a stacking structure (Ti/Al/Ti) of aluminum (Al) and titanium (Ti), a stacking structure (ITO/Al/ITO) of aluminum (Al) and indium tin oxide (ITO), or an APC alloy and may be formed of a single layer or multiple layers, but the embodiments of the present disclosure are not limited thereto.

The organic layer 152 may be disposed on the first electrode 151. The organic layer 152 may include one or more light-emitting structures (or light-emitting elements or elements) stacked on the first electrode 151 in the order or reverse order of a hole transfer layer and an electron transfer layer. For example, the hole transfer layer may include a hole transporting layer, a hole injecting layer, an electron blocking layer, a p-type charge generation layer, etc., but the embodiments of the present disclosure are not limited thereto. For example, the electron transfer layer may include an electron transporting layer, an electron injecting layer, a hole blocking layer, an n-type charge generation layer, etc., but the embodiments of the present disclosure are not limited thereto. The organic layer 152 may be an organic light-emitting layer, an inorganic light-emitting layer, a quantum dot light-emitting layer, a micro light-emitting diode, a micro mini light-emitting diode, etc., but the embodiments of the present disclosure area not limited thereto. For example, the organic layer 152 of the display panel 100 according to one embodiment of the present disclosure may include an organic light-emitting layer. The organic layer 152 may include a red light-emitting layer, a green light-emitting layer, and a blue light-emitting layer. The organic layer 152 may be a white light-emitting layer, but the embodiments of the present disclosure are not limited thereto. Hereinafter, a specific structure of the organic layer 152 according to one embodiment will be described.

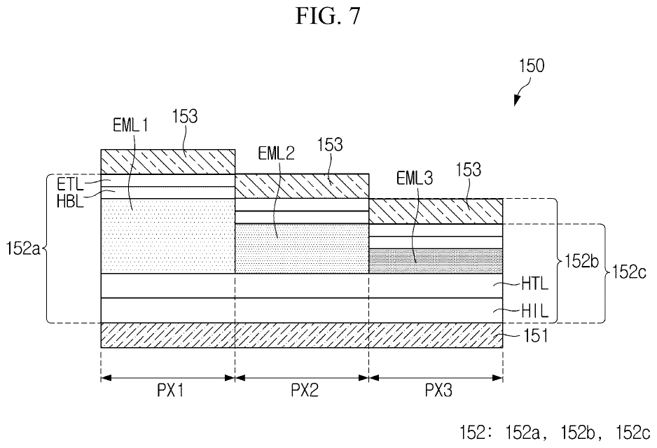

FIG. 7 is a specific cross-sectional view of a light-emitting part of FIG. 6.

Referring to FIG. 7, the light-emitting part 150 may include the first sub-pixel PX1, the second sub-pixel PX2, and the third sub-pixel PX3.

A thickness of the light-emitting part 150 in each sub-pixel PX1, PX2, or PX3 may be different, but the embodiments of the present disclosure are not limited thereto, and the thickness of the light-emitting part 150 in each sub-pixel PX1, PX2, or PX3 may be the same.

The organic layer 152 may include a first organic layer 152a disposed in the first sub-pixel PX1, a second organic layer 152b disposed in the second sub-pixel PX2, and a third organic layer 152c disposed in the third sub-pixel PX3. The light-emitting layers EML1, EML2, and EML3 of the organic layers 152a, 152b, and 152c may be physically separated, but lower layers and upper layers of the light-emitting layers EML1, EML2, and EML3 may be formed integrally across the sub-pixels PX1, PX2, and PX3. A thicknesses of each light-emitting layer EML1, EML2, or EML3 may be different. For example, a thickness of a first light-emitting layer EML1 may be the greatest, a thickness of a second light-emitting layer EML2 may be the second greatest, and a thickness of the third light-emitting layer EML3 may be the smallest, but the embodiments of the present disclosure are not limited thereto.

A hole injecting layer HIL may be disposed on the first electrode 151. The hole injecting layer HIL may be located between the first electrode 151 and the light-emitting layers EML1, EML2, and EML3. The hole injecting layer HIL may be formed integrally across the sub-pixels PX1, PX2, and PX3. For example, the hole injecting layer HIL may be formed of a hole injecting material that is one selected from MTDATA, CuPc, TCTA, NPB (NPD), HATCN, TDAPB, PEDOT/PSS, F4TCNQ, N-(biphenyl-4-yl)-9,9-dimethyl-N-(4-(9-phenyl-9H-carbazol-3-yl)phenyl)-9H-fluoren-2-amine, etc., but the embodiments of the present disclosure are not limited thereto.

A hole transporting layer HTL may be disposed on the hole injecting layer HIL. The hole transporting layer HTL may be located between the hole injecting layer HIL and the light-emitting layers EML1, EML2, and EML3. The hole transporting layer HTL may be formed integrally across the sub-pixels PX1, PX2, and PX3. The hole transporting layer HTL may be formed of one or more selected from the group consisting of arylamine-based materials, such as NPB (N,N-naphthyl-N,N′-phenyl benzidine), TPD (N,N′-bis-(3-methylphenyl)-N,N′-bis-(phenyl)-benzidine), PPD, TTBND, FFD, p-dmDPS, and TAPC, starbust aromatic amine-based materials, such as TCTA, PTDATA, TDAPB, TDBA, 4-a, and TCTA, and spiro and ladder type materials, such as Spiro-TPD, Spiro-mTTB, and Spiro-2, NPD (N, N-dinaphthylN,N′-diphenyl benzidine), s-TAD, and MTDATA(4,4′,4″-Tris(N-3-methylphenyl-N-phenyl-amino)-triphenylamine), but the embodiments of the present disclosure are not limited thereto.

The light-emitting layers EML1, EML2, and EML3 may be disposed on the hole transporting layer HTL. The first light-emitting layer EML1 may be disposed in the first sub-pixel PX1, the second light-emitting layer EML2 may be disposed in the second sub-pixel PX2, and the third light-emitting layer EML3 may be disposed in the third sub-pixel PX3.

A thicknesses of each light-emitting layer EML1, EML2, or EML3 may be different. For example, the first light-emitting layer EML1 may be formed in a thickness of 600 to 800 angstroms (10⁻¹⁰ meters), the second light-emitting layer EML2 may be formed in a thickness of 300 to 500 angstroms (10⁻¹⁰ meters), and the third light-emitting layer EML3 may be formed in a thickness of 100 to 300 angstroms (10⁻¹⁰ meters), but the embodiments of the present disclosure are not limited thereto.

Each of the first light-emitting layer EML1, the second light-emitting layer EML2, and the third light-emitting layer EML3 may include a material that may emit light in the visible light range by receiving and combining holes and electrons.

A hole blocking layer HBL may be disposed on each light-emitting layer EML1, EML2, or EML3. The hole blocking layer HBL may be disposed integrally across the sub-pixels PX1, PX2, and PX3.

An electron transporting layer ETL may be disposed on the electron blocking layer HBL. The electron transporting layer ETL may be disposed integrally across the sub-pixels PX1, PX2, and PX3. The electron transporting layer ETL may be formed of an anthracene derivative and lithium quinolate (Liq) or formed of one or more selected from oxadiazole, triazole, phenanthroline, benzoxazole, benzthiazole, or benzimidazole (e.g., 2-[4-(9,10-Di-2-naphthalenyl-2-anthracenyl)phenyl]-1-phenyl-1H-benzimidazole), but the embodiments of the present disclosure are not limited thereto.

The second electrode 153 may be disposed on the electron transporting layer ETL.

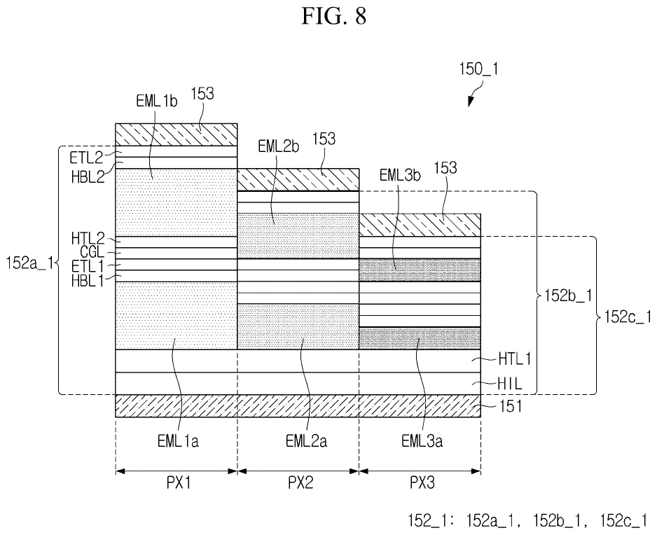

FIG. 8 is a specific cross-sectional view of a light-emitting part according to a modified example.

Referring to FIGS. 7 and 8, an organic layer 152_1 may include a first organic layer 152a_1 disposed in the first sub-pixel PX1, a second organic layer 152b_1 disposed in the second sub-pixel PX2, and a third organic layer 152c_1 disposed in the third sub-pixel PX3.

The light-emitting layers of each organic layer 152a_1, 152b_1, or 152c_1 may be physically separated, but the lower layers and upper layers of the light-emitting layers may be formed integrally across the sub-pixels PX1, PX2, and PX3. The thickness of each light-emitting layer may be different. For example, the thickness of the first light-emitting layer of the first sub-pixel may be the greatest, the thickness of the second light-emitting layer of the second sub-pixel may be the second greatest, and the thickness of the third light-emitting layer of the third sub-pixel may be the smallest, but the embodiments of the present disclosure are not limited thereto. In addition, the light-emitting layers of each organic layer 152a_1, 152b_1, or 152c_1 may be provided as two or more light-emitting layers.

A hole injecting layer HIL may be disposed on the first electrode 151. The hole injecting layer HIL may be located between the first electrode 151 and the light-emitting layers EML1a, EML2a, and EML3a. The hole injecting layer HIL may be formed integrally across the sub-pixels PX1, PX2, and PX3. For example, the hole injecting layer HIL may be formed of a hole injecting material that is one selected from MTDATA, CuPc, TCTA, NPB (NPD), HATCN, TDAPB, PEDOT/PSS, F4TCNQ, N-(biphenyl-4-yl)-9,9-dimethyl-N-(4-(9-phenyl-9H-carbazol-3-yl)phenyl)-9H-fluoren-2-amine, etc., but the embodiments of the present disclosure are not limited thereto.

A first hole transporting layer HTL1 may be disposed on the hole injecting layer HIL. The first hole transporting layer HTL1 may be located between the hole injecting layer HIL and light-emitting layers EML1a, EML2a, and EML3a. The first hole transporting layer HTL1 may be formed integrally across the sub-pixels PX1, PX2, and PX3. The first hole transporting layer HTL1 may be formed of one or more selected from the group consisting of arylamine-based materials, such as NPB (N,N-naphthyl-N,N′-phenyl benzidine), TPD (N,N′-bis-(3-methylphenyl)-N,N′-bis-(phenyl)-benzidine), PPD, TTBND, FFD, p-dmDPS, and TAPC, starbust aromatic amine-based materials, such as TCTA, PTDATA, TDAPB, TDBA, 4-a, and TCTA, and spiro and ladder type materials, such as Spiro-TPD, Spiro-mTTB, and Spiro-2, NPD (N,N-dinaphthylN,N′-diphenyl benzidine), s-TAD, and MTDATA(4,4′,4″-Tris(N-3-methylphenyl-N-phenyl-amino)-triphenylamine), but the embodiments of the present disclosure are not limited thereto.

The light-emitting layers EML1a, EML2a, and EML3a may be disposed on the first hole transporting layer HTL1. A 1-1 light-emitting layer EML1a may be disposed in the first sub-pixel PX1, a 2-1 light-emitting layer EML2 a may be disposed in the second sub-pixel PX2, and a 3-1 light-emitting layer EML3a may be disposed in the third sub-pixel PX3. Each of the light-emitting layers EML1a, EML2a, and EML3a may be the same as each of the light-emitting layers EML1, EML2, and EML3 of FIG. 7.

A thicknesses of each light-emitting layer EML1a, EML2a, or EML3a may be different. For example, the first light-emitting layer EML1 a may be formed in a thickness of 600 to 800 angstroms (10⁻¹⁰ meters), the second light-emitting layer EML2 a may be formed in a thickness of 300 to 500 angstroms (10⁻¹⁰ meters), and the third light-emitting layer EML3 a may be formed in a thickness of 100 to 300 angstroms (10⁻¹⁰ meters), but the embodiments of the present disclosure are not limited thereto.

A first hole blocking layer HBL1 may be disposed on each light-emitting layer EML1a, EML2a, or EML3a. The first hole blocking layer HBL1 may be formed integrally across the sub-pixels PX1, PX2, and PX3.

A first electron transporting layer ETL1 may be disposed on the first hole blocking layer HBL1. The first electron transporting layer ETL1 may be formed integrally across the sub-pixels PX1, PX2, and PX3. The first electron transporting layer ETL1 may be formed of an anthracene derivative and lithium quinolate (Liq) or formed of one or more selected from oxadiazole, triazole, phenanthroline, benzoxazole, benzthiazole, or benzimidazole (e.g., 2-[4-(9,10-Di-2-naphthalenyl-2-anthracenyl)phenyl]-1-phenyl-1H-benzimidazole), but the embodiments of the present disclosure are not limited thereto.

A common charge layer CGL may be disposed on the first electron transporting layer ETL1. The common charge layer CGL may be disposed between the first electron transporting layer ETL1 and a second hole transporting layer HTL2. The common charge layer CGL may include a conductive material, but the embodiments of the present disclosure are not limited thereto.

The second hole transporting layer HTL2 may be disposed on the common charge layer CGL. The second hole transporting layer HTL2 may be disposed between the hole blocking layer HBL and the light-emitting layers EML1b, EML2b, and EML3b. The second hole transporting layer HTL2 may be formed integrally across the sub-pixels PX1, PX2, and PX3. A material of the second hole transporting layer HTL2 may be the same as a material of the first hole transporting layer HTL1, but the embodiments of the present disclosure are not limited thereto.

The light-emitting layers EML1b, EML2b, and EML3b may be disposed on the second hole transporting layer HTL2. A 1-2 light-emitting layer EML1b may be disposed in the first sub-pixel PX1, a 2-2 light-emitting layer EML2 b may be disposed in the second sub-pixel PX2, and a 3-2 light-emitting layer EML3b may be disposed in the third sub-pixel PX3. Each of the light-emitting layers EML1b, EML2b, and EML3b may be the same as each of the light-emitting layers EML1a, EML2a, and EML3a.

A thicknesses of each light-emitting layer EML1b, EML2b, or EML3b may be different. For example, the 1-2 light-emitting layer EML1 b may be formed in a thickness of 600 to 800 angstroms (10⁻¹⁰ meters), the 2-2 light-emitting layer EML2 b may be formed in a thickness of 300 to 500 angstroms (10⁻¹⁰ meters), and the 3-2 light-emitting layer EML3 b may be formed in a thickness of 100 to 300 angstroms (10⁻¹⁰ meters), but the embodiments of the present disclosure are not limited thereto.

A second hole blocking layer HBL2 may be disposed on each light-emitting layer EML1b, EML2b, or EML3b. The second hole blocking layer HBL2 may be formed integrally across the sub-pixels PX1, PX2, and PX3.

A second electron transporting layer ETL2 may be disposed on the second hole blocking layer HBL2. The second electron transporting layer ETL2 may be formed integrally across the sub-pixels PX1, PX2, and PX3. The second electron transporting layer ETL2 may be formed of an anthracene derivative and lithium quinolate (Liq) or formed of one or more selected from oxadiazole, triazole, phenanthroline, benzoxazole, benzthiazole, or benzimidazole (e.g., 2-[4-(9,10-Di-2-naphthalenyl-2-anthracenyl)phenyl]-1-phenyl-1H-benzimidazole), but the embodiments of the present disclosure are not limited thereto.

The second electrode 153 may be disposed on the second electron transporting layer ETL2.

Referring back to FIG. 6, the second electrode 153 may be disposed on the organic layer 152. The second electrode 153 may be a transparent electrode that transmits light, but the embodiments of the present disclosure are not limited thereto. For example, the second electrode 153 may include a transparent conductive material, such as indium tin oxide (ITO) or indium zinc oxide (IZO), or a metal that transmits visible light, but the embodiments of the present disclosure are not limited thereto.

The bank 154 may be disposed to expose the first electrode 151. The bank 154 may be disposed to define the light-emitting area EA (EA1, EA2, and EA3) of the sub-pixels PX1, PX2, and PX3 and cover an edge portion (or a periphery) of the first electrode 151.

The non-light-emitting area NEA may be disposed around the light-emitting area EA. The bank 154 may be disposed in the non-light-emitting area NEA.

The light-emitting area EA may include the first light-emitting area EA1, the second light-emitting area EA2, and the third light-emitting area EA3 that are disposed in the sub-pixels PX1, PX2, and PX3, respectively. The non-light-emitting area NEA may include the first non-light-emitting area NEA1, a second non-light-emitting area (NEA2), and a third non-light-emitting area NEA3 that are disposed around the light-emitting areas EA1, EA2, and EA3, respectively.

That is, the first sub-pixel PX1 may include a first light-emitting area EA1 and a first non-light-emitting area NEA1 around the first light-emitting area EA1, the second sub-pixel PX2 may include a second light-emitting area EA2 and a second non-light-emitting area NEA2 around the second light-emitting area EA2, and the third sub-pixel PX3 may include a third light-emitting area EA3 and a third non-light-emitting area NEA3 around the third light-emitting area EA3. That is, each non-light-emitting area NEA1, NEA2, or NEA3 may correspond to a boundary between adjacent sub-pixels PX1, PX2, and PX3.

The bank 154 may be formed of an organic material, such as a benzocyclobutene resin, a polyimide resin, an acrylic resin, a photosensitive polymer, etc. However, the embodiments of the present disclosure are not limited thereto, and the bank 154 may further include a black-based material. For example, the bank 154 may be formed of a material containing black pigment, or an organic material, such as a benzocyclobutene resin, a polyimide resin, an acrylic resin, a photosensitive polymer, etc., but the embodiments of the present disclosure are not limited thereto. When the bank 154 is formed of a material containing black pigment or black dye, the bank 154 may be an opaque bank. When the bank 154 is formed of a material containing black pigment or black dye, it is possible to block external light or light reflected from the outside, thereby further increasing the luminance of the display apparatus.

A barrier RAS may be further disposed on the bank 154. As illustrated in FIG. 6, the barrier RAS may be disposed at all the boundaries between the sub-pixels PX1, PX2, and PX3 (in the non-display area NEA (NEA1, NEA2, and NEA3)), but the embodiments of the present disclosure are not limited thereto. The barrier RAS may be disposed directly on an upper surface of the bank 154, but the embodiments of the present disclosure are not limited thereto. The barrier RAS may serve to separate the organic layer 152 from the boundaries of adjacent sub-pixels PX1, PX2, and PX3. In some embodiments, the barrier may be omitted, and a trench may be formed in the bank 154. The trench may recess the bank 154 in the thickness direction.

A spacer 155 may be further disposed on the bank 154. The spacer 155 may be formed of the same material as the bank 154, but the embodiments of the present disclosure are not limited thereto. For example, the spacer 155 may be a transparent bank, but is not limited thereto, and the spacer 155 may be formed of the same material as the bank 154. For example, the spacer 155 may be disposed on at least one of the boundaries of the first to third sub-pixels PX1, PX2, and PX3, but the embodiments of the present disclosure are not limited thereto. The bank 154 and the spacer 155 may be formed of the same material and formed simultaneously through a halftone mask, but the embodiments of the present disclosure are not limited thereto.

The organic layer 152 may be disposed on the first electrode 151, the bank 154, and the spacer 155. The second electrode 153 may be disposed on the organic layer 152.

The encapsulation part 170 may be disposed on the second electrode 153. The encapsulation part 170 may include one or more insulating layers. For example, the encapsulation part 170 may include a first encapsulation layer 171, a second encapsulation layer 172 disposed on the first encapsulation layer 171, and a third encapsulation layer 173 disposed on the second encapsulation layer 172. The encapsulation part 170 may include one or more inorganic insulation material layers and one or more organic material layers. For example, the first encapsulation layer 171 and the third encapsulation layer 173 may include an inorganic insulation material, and the second encapsulation layer 172 may include an organic material, but the embodiments of the present disclosure are not limited thereto.

The touch part 180 may be disposed on the encapsulation part 170. The touch part 180 may include the touch buffer layer 181, a first touch conductive layer, the first touch insulating layer 183, the second touch insulating layer 184, and a second touch conductive layer. In some embodiments, one or more touch organic layers may be further disposed on the second touch conductive layer, but the embodiments of the present disclosure are not limited thereto.

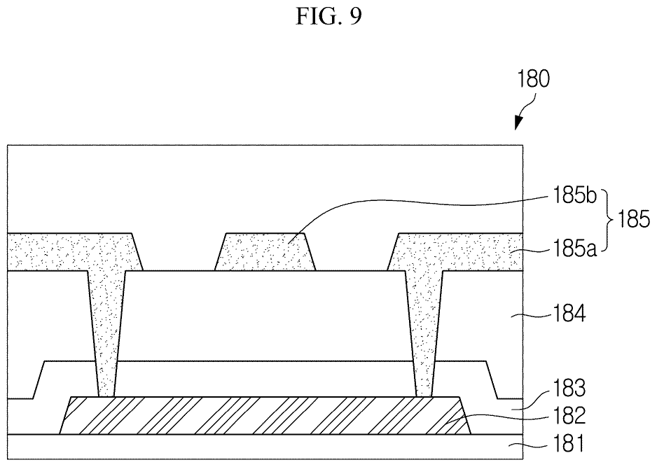

FIG. 9 is a cross-sectional view of a touch part according to FIG. 6.

Referring to FIGS. 6 and 9, the touch buffer layer 181 may be disposed on the encapsulation part 170. For example, a touch buffer layer 181 may be disposed on the third encapsulation layer 173. The touch buffer layer 181 may be formed of the same material as the buffer layer 102, but the embodiments of the present disclosure are not limited thereto.

The first touch conductive layer may be disposed on the touch buffer layer 181. The first touch conductive layer may include a bridge electrode 182. The bridge electrode 182 and a sensor electrode 185 to be described below may be disposed at each of the boundaries between adjacent sub-pixels PX1, PX2, and PX3. For example, the bridge electrode 182 and the sensor electrode 185 may be disposed in the non-light-emitting areas NEA1, NEA2, and NEA3. The bridge electrode 182 and the sensor electrode 185 may overlap the black matrix BM to be described below in the thickness direction. The black matrix BM may cover the bridge electrode 182 and the sensor electrode 185. Accordingly, the bridge electrode 182 and the sensor electrode 185 can be prevented from being visible from the outside.

The first touch insulating layer 183 and the second touch insulating layer 184 disposed on the first touch insulating layer 183 may be disposed on the first touch conductive layer. The first touch insulating layer 183 and the second touch insulating layer 184 disposed on the first touch insulating layer 183 can prevent a short circuit between the first touch conductive layer and the second touch conductive layer. The first touch insulating layer 183 may be formed of silicon oxide (SiOₓ), silicon nitride (SiNₓ), or multiple layers thereof, but the embodiments of the present disclosure are not limited thereto. The second touch insulating layer 184 may include an organic insulation material, but the embodiments of the present disclosure are not limited thereto, and the second touch insulating layer 184 may include the same material as the first touch insulating layer 183.

The second touch conductive layer may be disposed on the second touch insulating layer 184. The second touch conductive layer may include a first sensor electrode 185a and a second sensor electrode 185b. The sensor electrode 185 may include the first sensor electrode 185a extending in the first direction DR1 (see FIG. 1) and the second sensor electrode 185b extending in the second direction DR2 (see FIG. 1) different from the first direction DR1.

The bridge electrode 182 may be electrically connected to the first sensor electrode 185a through a contact hole formed in the first touch insulating layer 183 and the second touch insulating layer 184. For example, the first sensor electrode 185a and the bridge electrode 182 may extend in the first direction DR1 (see FIG. 1).

The sensor electrode 185 and the bridge electrode 182 may include a metallic material. For example, the sensor electrode 185 and the bridge electrode 182 may be formed of titanium (Ti), nickel (Ni), aluminum (Al), or an alloy thereof and formed of a triple layer, such as titanium (Ti)/aluminum (Al)/titanium (Ti), but the embodiments of the present disclosure are not limited thereto.

Referring back to FIG. 6, the filter insulating layer 114 may be disposed on the sensor electrode 185. The filter insulating layer 114 may be formed of an inorganic insulation material, such as silicon nitride (SiNₓ) or silicon oxide (SiOₓ), but the embodiments of the present disclosure are not limited thereto.

The black matrix BM may be disposed on the filter insulating layer 114. The black matrix BM may include a black-based material. For example, the black matrix BM may include a light-blocking material or a light-absorbing material. For example, the black matrix BM may be formed of a material including a black pigment, a black dye, etc. The black matrix BM may cover the bridge electrode 182 and the sensor electrode 185. Accordingly, the bridge electrode 182 and the sensor electrode 185 can be prevented from being visible from the outside. For example, a width of the black matrix BM may be smaller than a width of the bank 154.

For example, spacing distances between an end of the black matrix BM and boundaries between the light-emitting areas EA1, EA2, and EA3 and the non-light-emitting areas NEA1, NEA2, and NEA3 may be longer than spacing distances between an end of the bank 154 and the boundaries between the light-emitting areas EA1, EA2, and EA3 and the non-light-emitting areas NEA1, NEA2, and NEA3. The end of the bank 154 may be aligned with the boundaries between the light-emitting areas EA1, EA2, and EA3 and the non-light-emitting areas NEA1, NEA2, and NEA3, but the embodiments of the present disclosure are not limited thereto. In the case of the display panel 100 according to one embodiment, since the bank 154 may include a black-based material and the spacing distances between an end of the black matrix BM and boundaries between the light-emitting areas EA1, EA2, and EA3 and the non-light-emitting areas NEA1, NEA2, and NEA3 may be longer than spacing distances between an end of the bank 154 and the boundaries between the light-emitting areas EA1, EA2, and EA3 and the non-light-emitting areas NEA1, NEA2, and NEA3, light emitted from the light-emitting areas EA1, EA2, and EA3 may be emitted upward with a greater viewing angle as much as a spacing space between the end of the black matrix BM and the boundaries between the light-emitting areas EA1, EA2, and EA3 and the non-light-emitting areas NEA1, NEA2, and NEA3. Accordingly, it is possible to minimize a reduction in luminance according to a viewing angle. However, when the spacing distances between an end of the black matrix BM and boundaries between the light-emitting areas EA1, EA2, and EA3 and the non-light-emitting areas NEA1, NEA2, and NEA3 may be longer than spacing distances between an end of the bank 154 and the boundaries between the light-emitting areas EA1, EA2, and EA3 and the non-light-emitting areas NEA1, NEA2, and NEA3 and the bank 154 is formed of only a transparent material, light incident from the outside may be reflected by the bank 154, resulting in visible ring-shaped spots. However, in the case of the display panel 100 according to one embodiment, the light incident from the outside may be absorbed or blocked by the bank 154 including a black-based material, thereby preventing the occurrence of the ring-shaped spots.

The color filters 191, 192, and 193 may be disposed on the black matrix BM. The color filters 191, 192, and 193 may be disposed on the first to third sub-pixels PX1, PX2, and PX3, respectively, and may block specific colors from light emitted from the light-emitting area EA1, EA2, and EA3 of the sub-pixels PX1, PX2, and PX3. A first color filter 191 may be provided to block light of other colors not including red (R) light. In this case, the first color filter 191 may be provided as a red color filter. The second color filter 192 may be provided to block light of other colors not including green (G) light. In this case, a second color filter 192 may be provided as a green color filter. A third color filter 193 provided in the third sub-pixel PX3 may be provided to block light of other colors not including blue (B) light. In this case, the third color filter 193 may be provided as a blue color filter. However, the embodiments of the present disclosure are not limited thereto.

For example, each color filter 191, 192, or 193 may come into direct contact with side and upper surfaces of the black matrix BM. For example, each color filter 191, 192, or 193 may be spaced apart from the boundaries of adjacent sub-pixels PX1, PX2, and PX3, but the embodiments of the present disclosure are not limited thereto, and the color filters 191, 192, and 193 may overlap each other in the thickness direction. For example, one or more of the first color filter 191, the second color filter 192, and the third color filter 193 may overlap each other on the black matrix BM. For example, the second color filter 192 may be disposed on the black matrix BM, and the first color filter 191 may be disposed on the second color filter 192. For example, the third color filter 193 may be disposed on the black matrix BM, and the first color filter 191 may be disposed on the third color filter 193.

The planarization layer OC may be disposed on the color filters 191, 192, and 193. The planarization layer OC may serve to planarize a step formed by the color filters 191, 192, and 193. For example, the planarization layer OC may include an organic insulation material.

Hereinafter, the first optical area DA1 will be described. For contents that are substantially the same as those described in the normal area NA among the descriptions of the first optical area DA1, the same reference numerals are given, and the overlapping contents may be omitted or briefly described.

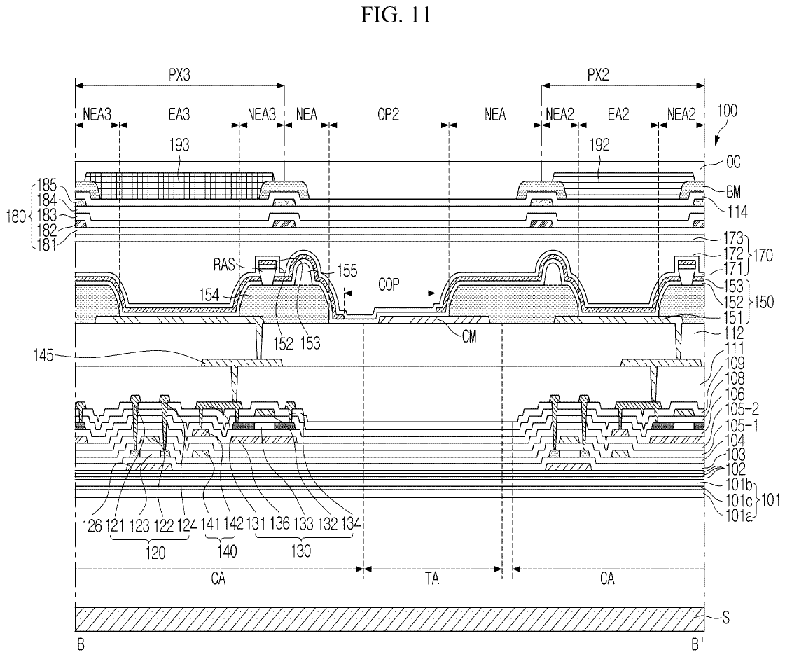

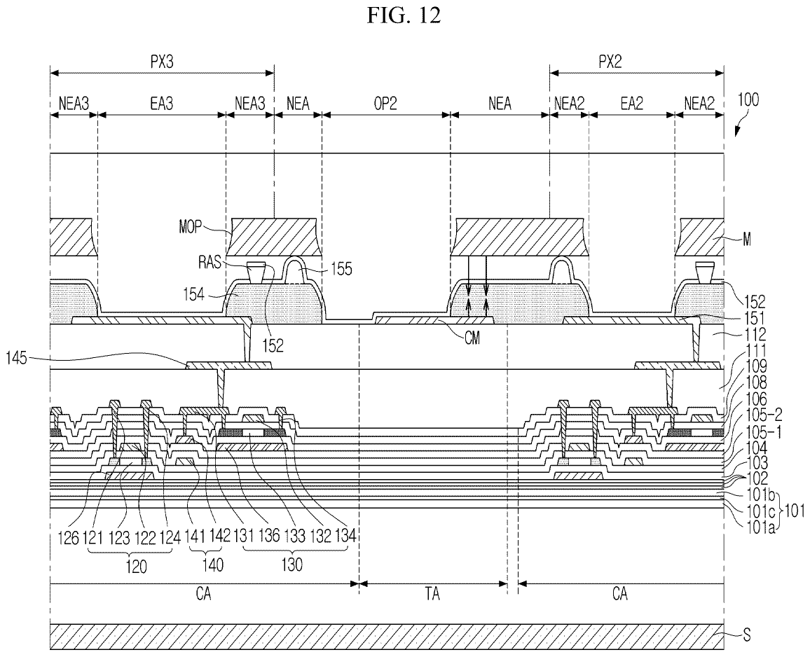

FIG. 10 is a plan view of a first optical area of the display area according to one embodiment. FIG. 11 is a cross-sectional view along line B-B′ in FIG. 10. FIG. 12 is a schematic view illustrating a process of forming an organic layer by a deposition mask.

Referring to FIGS. 10 to 12, the optical electronic device S may be disposed below the display panel 100. The optical electronic device S may be disposed to overlap the first optical area DA1 of the display panel 100.

The first optical area DA1 may have a lower PPI than the normal area NA. Accordingly, the size of the circuit area CA of the first optical area DA1 may be smaller than the size of the circuit area CA of the normal area NA. The circuit area CA may extend in the first direction DR1.

The first optical area DA1 may further include the transmissive area TA and a non-transmissive area NTA disposed around the transmissive area TA.

The transmissive area TA and the non-transmissive area NTA may have different light transmittances. The light transmittance of the transmissive area TA may be higher than the light transmittance of the non-transmissive area NTA.

The transmissive area TA may be an area capable of light transmission in which light entering from the outside of the display panel 100 may pass through the display panel 100 and may be emitted to the outside of the display panel 100.

Through the transmissive area TA, external light may pass through the display panel 100 and reach the optical electronic device S.

The transmissive area TA may be disposed between adjacent circuit areas CA in the second direction DR2. The transmissive area TA may be disposed between adjacent first circuit lines CL1 and disposed between adjacent second circuit lines CL2.

The transmissive area TA may be repeatedly disposed in the first direction DR1. The circuit area CA and the transmissive area TA may be alternately repeated in the second direction DR2.

The non-transmissive area NTA may be an area incapable of light transmission which is disposed around the transmissive area TA and in which light entering from the outside of the display panel 100 may not pass through the display panel 100.

At least one metal layer may be disposed in the non-transmissive area NTA. In the non-transmissive area NTA, the circuit area CA, the light-emitting part 150 (151, 152, and 153), and the circuit lines CL1 and CL2 may be disposed, and at least a part of the non-transmissive area NEA and the light-emitting area EA (EA1, EA2, and EA3) may be disposed.

That is, the non-transmissive area NTA may overlap at least a part of the non-transmissive area NEA, the light-emitting area EA (EA1, EA2, and EA3), the circuit area CA, the first electrode 151, and the circuit lines CL1 and CL2.

The transmissive area TA may not overlap the light-emitting area EA, the circuit area CA, the first electrode 151, and the circuit lines CL1 and CL2. In addition, a light-blocking layer may be formed in the light-emitting area EA, but the light-blocking layer may not be formed in the transmissive area TA.

A close-contact member CM may be disposed in the transmissive area TA. The close-contact member CM may include a transparent and magnetic material. For example, the close-contact member CM may include magnetite (Fe₃O₄).

The close-contact member CM may be disposed on the same layer as the first electrode 151. That is, when the first electrode 151 is disposed on the second protective layer 112, the close-contact member CM may be disposed on the second protective layer 112. Accordingly, the arrangement of the transistors 120 and 130, the storage capacitor 140, the circuit lines CL1 and CL2, etc. of the circuit area CA may not be affected, and the close-contact member CM may be disposed in the same area in a plan view. That is, a separate space for the close-contact member CM may be unnecessary.

The close-contact member CM may be separated from the first electrode 151 and disposed to be spaced apart from each other. Each close-contact member CM may be patterned to have a plurality of island shapes, but is not limited thereto.

In the process of depositing the organic layer 152, a deposition mask M (or a fine metal mask (FMM)) may be used. The deposition mask M may define a mask opening MOP passing through the deposition mask M in the thickness direction. The mask opening MOP may be disposed to correspond to the light-emitting area EA and the opening OP (OP1, OP2, and OP3).

The deposition mask M may be used in the process of depositing a component that is separately disposed in each sub-pixel PX1, PX2, or PX3 among components of the organic layer 152. For example, but the embodiments of the present disclosure are not limited thereto, the deposition mask M may be used in the process of depositing the light-emitting layers EML1, EML2, and EML3 (see FIG. 7) of the organic layer 152.

The first optical area DA1 may further include the opening OP (OP1, OP2, and OP3) passing through the bank 154. The opening OP may be defined by the bank 154. The opening OP may not expose the first electrode 151 and may expose at least a part of the close-contact member CM and/or the second protective layer 112.

The opening OP may include a first opening OP1 in which the first light-emitting area EA1 is substantially the same as the flat surface shape, a second opening OP2 in which the second light-emitting area EA2 is substantially the same as the flat surface shape, and a third opening OP3 in which the third light-emitting area EA3 is substantially the same as the flat surface shape.

The organic layer 152 disposed in each opening OP (OP1, OP2, and OP3) may have the same stacking structure as one of the sub-pixels PX1, PX2, and PX3) of FIG. 7 or 8. The organic layers 152 disposed in adjacent openings OP may have different stacking structures.

The embodiments of the present disclosure are not limited thereto, but, for example, the stacking structure of the organic layer 152 disposed in the first opening OP1 may be the same as the stacking structure of the organic layer 152 disposed in the first light-emitting area EA1 of the first sub-pixel PX1, the stacking structure of the organic layer 152 disposed in the second opening OP2 may be the same as the stacking structure of the organic layer 152 disposed in the second light-emitting area EA2 of the second sub-pixel PX2, and the stacking structure of the organic layer 152 disposed in the third opening OP3 may be the same as the stacking structure of the organic layer 152 disposed in the third light-emitting area EA3 of the third sub-pixel PX3.

In each of the openings OP1, OP2, and OP3, the organic layer 152 may come into direct contact with the second protective layer 112, but is not limited thereto.

The embodiments of the present disclosure are not limited thereto, but, in an area in which each opening OP1, OP2, or OP3 is disposed, the color filters 191, 192, and 193 (see FIG. 6) may be omitted. Accordingly, the optical electronic device S can more smoothly receive external light of the display apparatus 1.

The second electrode 153 may be disposed in each opening OP1, OP2, or OP3, and an opening COP passing through the second electrode 153 in the thickness direction may be defined in each opening OP1, OP2, or OP3.

The opening COP may be disposed in each opening OP1, OP2, or OP3, and the entire area may be disposed in each opening OP1, OP2, or OP3, but the embodiments of the present disclosure are not limited thereto.

As least a part of the opening COP may be disposed in the transmissive area TA. Since the opening COP is disposed in the transmissive area TA, it is possible to increase the light transmittance of the transmissive area TA.

The first encapsulation layer 171 may come into direct contact with the organic layer 152 in the opening COP, but is not limited thereto.

As the close-contact member CM is disposed in the transmissive area TA, the deposition mask M used in the process of depositing the organic layer 152 may further come into close contact therewith due to the magnetism of the close-contact member CM. Accordingly, each layer of the organic layer 152 can be deposited more smoothly at a desired location, thereby minimizing a spot defect (e.g., shadows or shadow mura) of the display panel 100. Furthermore, it is possible to enable the operation defect prevention, luminance improvement, etc. of the display apparatus 1, thereby reducing power consumption.

In addition, since the close-contact member CM includes a transparent magnetic material, it is possible to minimize a reduction in the light transmittance of the transmissive area TA.

Hereinafter, other embodiments of the present disclosure will be described. For contents substantially the same as those described with reference to FIGS. 1 to 12 among components included in other embodiments, the same reference numerals are given, and the overlapping contents may be omitted or briefly described.

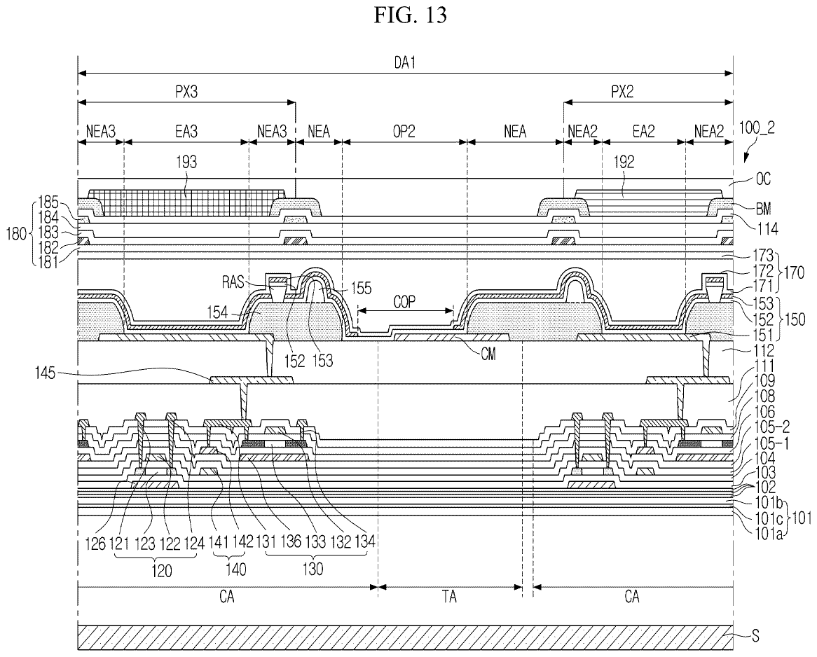

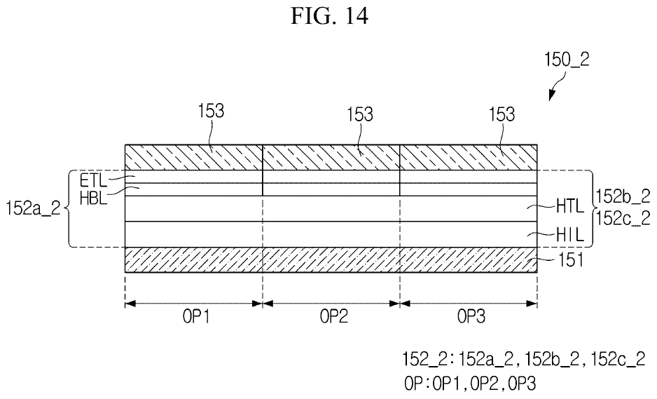

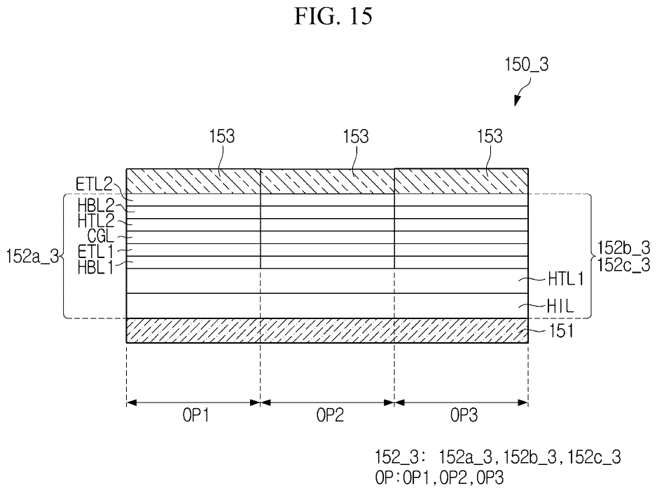

FIG. 13 is a view illustrating a cross section of a first optical area according to another embodiment. FIG. 14 is a specific cross-sectional view of a light-emitting part of FIG. 13. FIG. 15 is a specific cross-sectional view of a light-emitting part according to a modified example of FIG. 14.

FIGS. 14 and 15 illustrate cross-sections of light-emitting parts 150_2 and 150_3 disposed in each opening OP1, OP2, or OP3. Cross-sectional structures of the light-emitting parts 150_2 and 150_3 in the light-emitting area EA (EA1, EA2, and EA3) may be substantially the same as the cross-sectional structures of the light-emitting parts of FIGS. 7 and 8.

Referring to FIGS. 13 to 15, in a display panel 100_2 of the present embodiment, the light-emitting parts 150_2 and 150_3 in the opening OP (OP1, OP2, and OP3) and the light-emitting area EA (EA1, EA2, and EA3) may have different cross-sectional structures.

In FIG. 14, the light-emitting part 150_2 disposed in each opening OP1, OP2, or OP3 may not be disposed in each opening OP1, OP2, or OP3 because the stacking structure deposited by the deposition mask M is omitted. For example, in each organic layer 152_2 (152a_2, 152b_2, and 152c_2), the light-emitting layers EML1, EML2, and EML3 of FIG. 7 may be omitted and may not be disposed in each opening OP1, OP2, or OP3.

Accordingly, in each opening OP1, OP2, or OP3, a hole-blocking layer HBL may be disposed on a hole transporting layer HTL of each organic layer 152_2 (152a_2, 152b_2, and 152c_2), and the hole transporting layer HTL may come into direct contact with the hole blocking layer HBL.

In FIG. 15, the light-emitting part 150_3 disposed in each opening OP1, OP2, or OP3 may not be disposed in each opening OP1, OP2, or OP3 because the stacking structure deposited by the deposition mask M is omitted. For example, in each organic layer 152_2 (152a_3, 152b_3, and 152c_3), the light-emitting layers EML1a, EML2a, EML3a, EML1b, EML2b, and EML3b of FIG. 8 may be omitted and may not be disposed in each opening OP1, OP2, or OP3.

Accordingly, in each opening OP1, OP2, or OP3, the first hole blocking layer HBL1 may be disposed on the first hole transporting layer HTL1 of each organic layer 152_3 (152a_3, 152b_3, and 152c_3), and the second hole blocking layer HBL2 may be disposed on the second hole transporting layer HTL2.

In each opening OP1, OP2, or OP3, the first hole transporting layer HTL1 may come into direct contact with the first hole blocking layer HBL1, and the second hole transporting layer HTL2 may come into direct contact with the second hole blocking layer HBL2.

Since the light-emitting layers EML1, EML2, and EML3, or EML1a, EML2a, EML3a, EML1b, EML2b, and EML3b disposed in each opening OP1, OP2, or OP3 are omitted, it is possible to increase the light transmittance in the transmissive area TA. Accordingly, the optical electronic device S can receive external light more smoothly.

Even in this case, since the close-contact member CM is disposed, close-contact of a deposition mask M_2 is possible, and the respective layers of the organic layers 152_2 and 152_3 can be deposited more smoothly at desired locations, thereby minimizing a spot defect (e.g., shadow or shadow mura) of the display panel 100_2.

The deposition mask for forming the light-emitting layers EML1, EML2, and EML3, or EML1a, EML2a, EML3a, EML1b, EML2b, and EML3b may have two areas having different patterns.

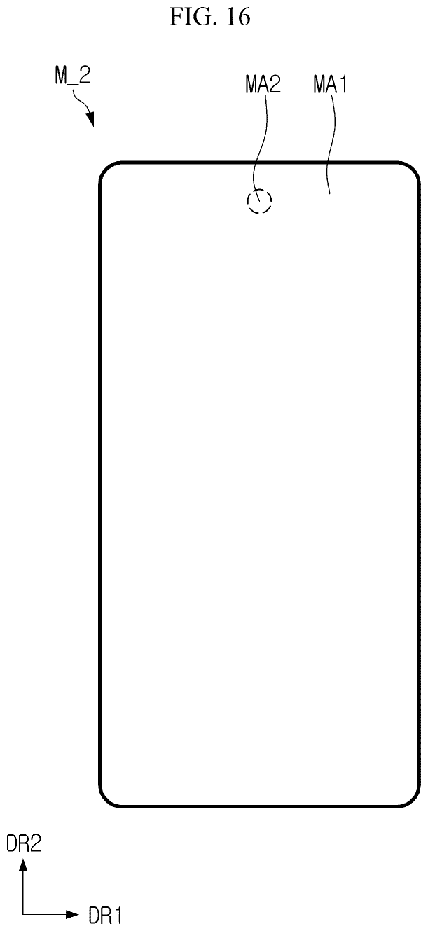

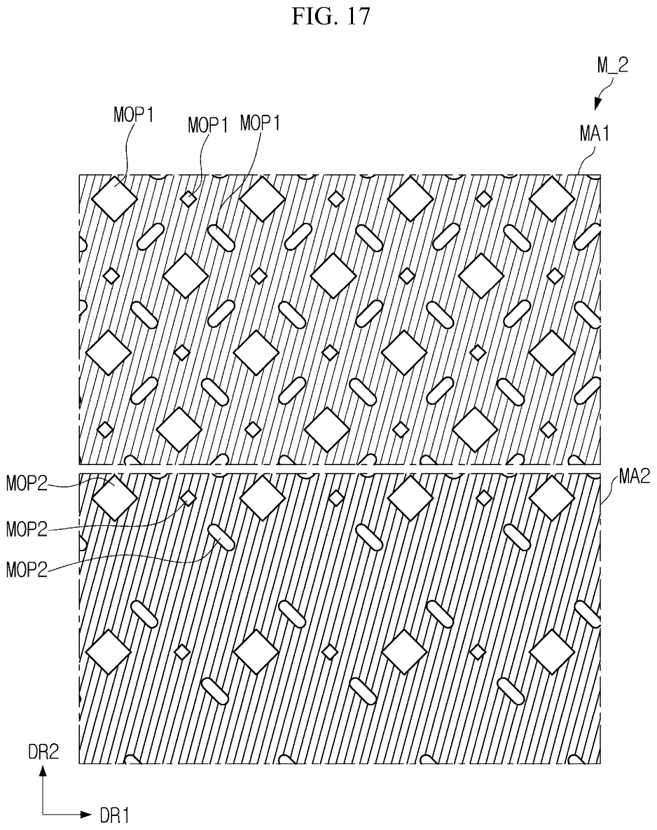

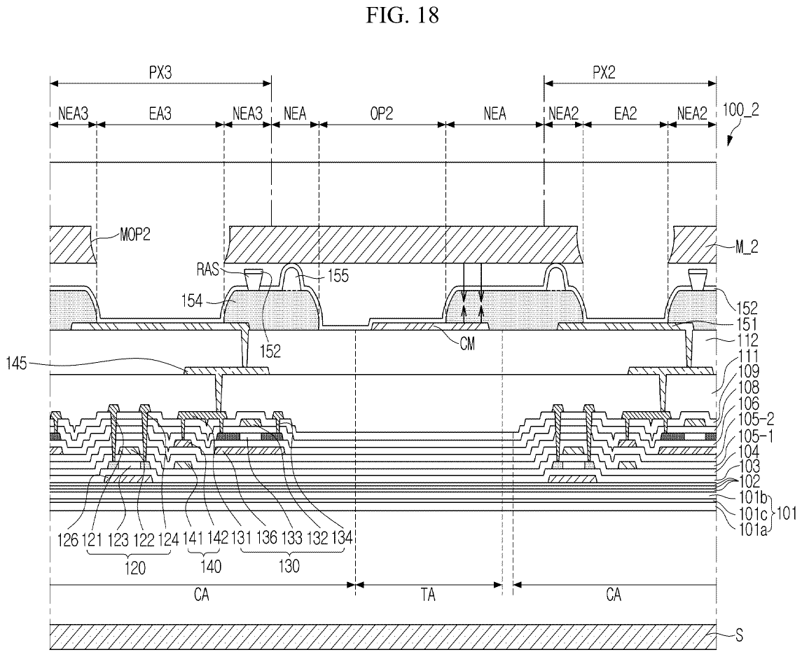

FIG. 16 is a plan view of a deposition mask for depositing an organic layer of a display panel of FIG. 13. FIG. 17 is an enlarged view of a first mask area and a second mask area of the deposition mask of FIG. 16. FIG. 18 is a schematic view illustrating a process of forming an organic layer by the deposition mask of FIG. 16.

Referring further to FIGS. 16 to 18, the deposition mask M_2 for depositing the organic layers 152_2 and 152_3 of the display panel 100_2 of FIG. 13 may include a first mask area MA1 and a second mask area MA2 that have different arrangement patterns of mask openings MOP1 and MOP2.

The first mask area MA1 may correspond to the normal area NA (see FIG. 1) of the display area DA, and the second mask area MA2 may correspond to the first optical area DA1 of the display area DA.

The first mask area MA1 may include a first mask opening MOP1, and the second mask area MA2 may include a second mask opening MOP2. A pattern of the first mask opening MOP1 disposed in the first mask area MA1 may differ from a pattern of the second mask opening MOP2 disposed in the second mask area MA2.

The first mask opening MOP1 may be disposed to correspond to each light-emitting area EA (see FIG. 5) of the normal area NA (see FIG. 1). The shape and location of the first mask opening MOP1 may correspond to each light-emitting area EA (see FIG. 5) of the normal area NA (see FIG. 1).

The second mask opening MOP2 may be disposed to correspond to the light-emitting area EA (see FIG. 10) of the first optical area DA1. The shape and location of the second mask opening MOP2 may correspond to the light-emitting area EA (see FIG. 10) of the first optical area DA1.

An arrangement density of the first mask opening MOP1 may be greater than an arrangement density of the second mask opening MOP2.

During the process of depositing the organic layers 152_2 and 152_3 by the deposition mask M_2, each opening OP1, OP2, or OP3 may be covered by the deposition mask M_2.

Since the mask openings MOP1 and MOP2 disposed on the deposition mask M_2 are disposed in different patterns in different areas, the process of depositing the display panel 100_2 having the normal area NA and the first optical area DA1 can be more smoothly.

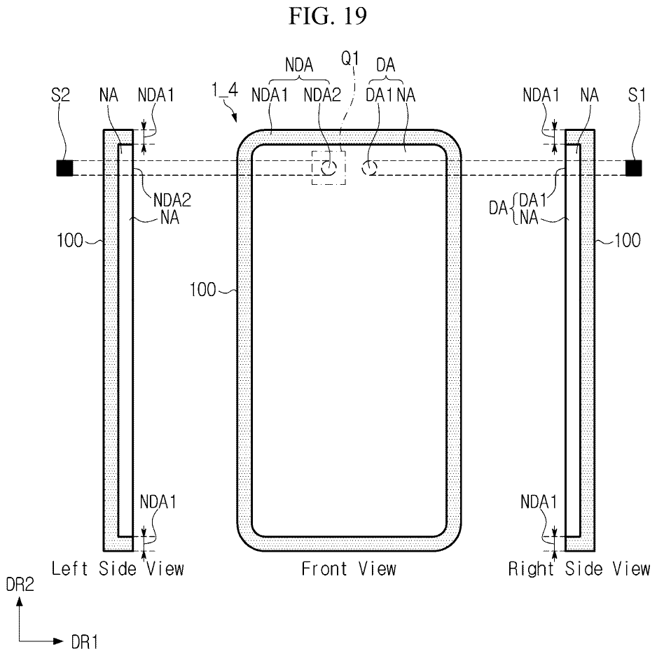

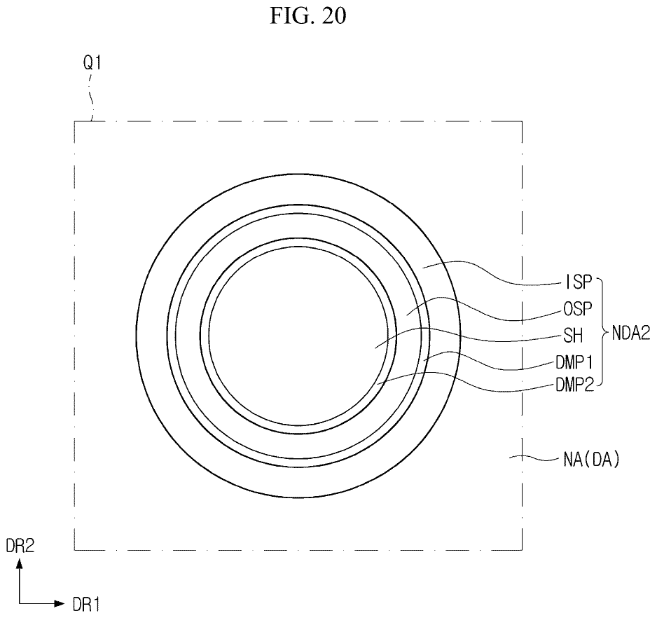

FIG. 19 is a schematic plan view of a display apparatus according to another embodiment. FIG. 20 is an enlarged view of area Q1 in FIG. 19.

Referring to FIGS. 19 and 20, the display area DA of a display apparatus 1_4 may include the normal area NA and the first optical area DA1. The non-display area NDA may include a first non-display area NDA1 and a second non-display area NDA2. The first non-display area NDA1 may be substantially the same as the non-display area NDA of FIGS. 1 to 4. The second non-display area NDA2 may be disposed in the display area DA (or the normal area NA). The second non-display area NDA2 may be surrounded by the display area DA (or the normal area NA).

Here, at least a part of the first optical area DA1 may overlap the first optical electronic device S1, and at least a part of the second non-display area NDA2 may overlap the second optical electronic device S2.

For example, the first optical electronic device S1 may be a detection sensor, such as a proximity sensor, an illuminance sensor, etc., and the second optical electronic device S2 may be a camera. For example, the detection sensor may be an infrared sensor for detecting infrared rays.

The size of the second non-display area NDA2 may be greater than the size of the first optical area DA1.

The second non-display area NDA2 may include an outer separation area OSP between a sensor hole SH and the display area DA, a first dam area DMP1 between the outer separation area OSP and the display area DA, an inner separation area ISP between the first dam area DMP1 and the display area DA, and a second dam area DMP2 between the outer separation area OSP and the sensor hole SH. The second non-display area NDA2 may completely surround the sensor hole SH.

The display panel 100 may be omitted in the sensor hole SH. That is, the sensor hole SH may pass through the display panel 100 in the thickness direction.

A display apparatus according to various embodiments of the present disclosure may be described as follows.

According to embodiments of the present disclosure, there is provided a display apparatus including a substrate, an optical area including a transmissive area and a non-transmissive area having different light transmittances and for displaying a screen, a thin film transistor disposed on the substrate, a protective layer disposed on the thin film transistor, a light-emitting part disposed on the protective layer, and a transparent and magnetic close-contact member disposed on the protective layer, in which the light-emitting part is disposed in the non-transmissive area, and the transparent and magnetic close-contact member is disposed in the transmissive area.

According to various embodiments of the present disclosure, the light-emitting part may include a first electrode disposed on the protective layer, an organic layer disposed on the first electrode, and a second electrode disposed on the organic layer, and the transparent and magnetic close-contact member may be disposed on the same layer as the first electrode.

According to various embodiments of the present disclosure, the display apparatus may further include a bank disposed on the first electrode, in which the bank may define a light-emitting area passing through the bank in the thickness direction to expose the first electrode, and an opening passing through the bank in the thickness direction to expose at least one of the transparent and magnetic close-contact member and the protective layer.

According to various embodiments of the present disclosure, the light-emitting area may be disposed in the non-transmissive area, and at least a part of the opening may be disposed in the transmissive area.

According to various embodiments of the present disclosure, the organic layer may be disposed across the light-emitting area and the opening, the organic layer disposed in the light-emitting area may have a hole injecting layer, a hole transporting layer, an organic layer, a hole blocking layer, and an electron transporting layer that are sequentially stacked, and the organic layer disposed in the opening may have a hole injecting layer, a hole transporting layer, a hole blocking layer, and an electron transporting layer that are sequentially stacked.

According to various embodiments of the present disclosure, the hole transporting layer and the hole blocking layer in the opening may be in direct contact with each other in the opening.

According to various embodiments of the present disclosure, the second electrode may define another opening passing through the second electrode in the thickness direction in the opening.

According to various embodiments of the present disclosure, the display apparatus may further include an encapsulation part including a first encapsulation layer disposed on the second electrode, a second encapsulation layer disposed on the first encapsulation layer, and a third encapsulation layer disposed on the second encapsulation layer, in which the first encapsulation layer may be in direct contact with the organic layer in the opening.

According to various embodiments of the present disclosure, the organic layer may be in direct contact with the protective layer in the opening.

According to various embodiments of the present disclosure, the display apparatus may further include a plurality of first circuit lines electrically connected to the thin film transistor and extending in a first direction, and a plurality of second circuit lines electrically connected to the thin film transistor and extending in a second direction intersecting the first direction, in which the plurality of first circuit lines may be repeatedly disposed in the second direction, and the plurality of second circuit lines may be repeatedly disposed in the first direction, and the transparent and magnetic close-contact member may be disposed between a plurality of adjacent first circuit lines and between a plurality of adjacent second circuit lines.

According to various embodiments of the present disclosure, a light transmittance of the transmissive area may be higher than a light transmittance of the non-transmissive area.

According to various embodiments of the present disclosure, the display apparatus may further include a normal area disposed around an optical area and having a higher pixels per inch (PPI) than the optical area.

According to various embodiments of the present disclosure, the transparent and magnetic close-contact member may include magnetite (Fe₃O₄).

According to various embodiments of the present disclosure, the display apparatus may further include an optical electronic device that is disposed to overlap the optical area and to receive external light.

According to embodiments of the present disclosure, there is provided a display apparatus including a display area for displaying a screen, a non-display area disposed outside the display area, an optical area including a transmissive area and a non-transmissive area having different light transmittances, a normal area having a higher PPI than the optical area, a light-emitting part disposed across the non-transmissive area of the optical area and the normal area, a transparent and magnetic close-contact member disposed in the transmissive area, and an optical electronic device that is disposed to overlap the optical area and to receive external light.

According to various embodiments of the present disclosure, the display apparatus may further include a substrate in which a transmissive area and a non-transmissive area are defined, a thin film transistor disposed on the substrate, a protective layer disposed on the thin film transistor, and a first electrode disposed on the protective layer, in which the transparent and magnetic close-contact member may be disposed on the protective layer.

According to various embodiments of the present disclosure, the display apparatus may further include a bank disposed on the first electrode, in which the bank may define a light-emitting area passing through the bank in the thickness direction to expose the first electrode, and an opening passing through the bank in the thickness direction to expose at least one of the transparent and magnetic close-contact member and the protective layer.

According to various embodiments of the present disclosure, the light-emitting area may be disposed in the non-transmissive area, and at least a part of the opening may be disposed in the transmissive area.

According to various embodiments of the present disclosure, the first electrode and the transparent and magnetic close-contact member may be disposed on the same layer.

According to various embodiments of the present disclosure, the display apparatus may further include a light-emitting part disposed in the display area, a thin film transistor electrically connected to the light-emitting part in the display area, a plurality of first circuit lines electrically connected to the thin film transistor and extending in a first direction, and a plurality of second circuit lines electrically connected to the thin film transistor and extending in a second direction intersecting the first direction, in which the plurality of first circuit lines may be repeatedly disposed in the second direction, the plurality of second circuit lines may be repeatedly disposed in the first direction, and a close-contact member may be disposed between a plurality of adjacent first circuit lines and between a plurality of adjacent second circuit lines.

Although the embodiments have been described above with reference to the accompanying drawings, those skilled in the art to which the present disclosure pertains will be able to understand that the above-described technical configuration can be carried out in other specific forms without changing the technical spirit or essential features thereof. Accordingly, it should be understood that the above-described embodiments are illustrative and not restrictive in all respects. In addition, the scope of the embodiments is determined by the appended claims rather than detailed description. In addition, the meaning and scope of the claims and all changed or modified forms derived from the equivalent concept thereof should be construed as being included in the scope of the embodiments.

What is claimed is:

1. A display apparatus, comprising:
a substrate;
an optical area including a transmissive area and a non-transmissive area having different light transmittances and for displaying a screen;
a thin film transistor disposed on the substrate;
a protective layer disposed on the thin film transistor;
a light-emitting part disposed on the protective layer; and
a transparent and magnetic close-contact member disposed on the protective layer,
wherein the light-emitting part is disposed in the non-transmissive area, and the transparent and magnetic close-contact member is disposed in the transmissive area.

2. The display apparatus of claim 1, wherein the light-emitting part includes a first electrode disposed on the protective layer, an organic layer disposed on the first electrode, and a second electrode disposed on the organic layer, and
wherein the transparent and magnetic close-contact member is disposed on a same layer as the first electrode.

3. The display apparatus of claim 2, further comprising a bank disposed on the first electrode,
wherein the bank defines:
a light-emitting area passing through the bank in a thickness direction to expose the first electrode; and
an opening passing through the bank in the thickness direction to expose at least one of the transparent and magnetic close-contact member and the protective layer.

4. The display apparatus of claim 3, wherein the light-emitting area is disposed in the non-transmissive area, and
wherein at least a part of the opening is disposed in the transmissive area.

5. The display apparatus of claim 4, wherein the organic layer is disposed across the light-emitting area and the opening,
wherein the organic layer disposed in the light-emitting area has a hole injecting layer, a hole transporting layer, an organic layer, a hole blocking layer, and an electronic transporting layer that are sequentially stacked, and
wherein the organic layer disposed in the opening has a hole injecting layer, a hole transporting layer, a hole blocking layer, and an electronic transporting layer that are sequentially stacked.

6. The display apparatus of claim 5, wherein the hole transporting layer and the hole blocking layer in the opening are in direct contact with each other in the opening.

7. The display apparatus of claim 3, wherein the second electrode defines another opening passing through the second electrode in the thickness direction in the opening.

8. The display apparatus of claim 7, further comprising: an encapsulation part including a first encapsulation layer disposed on the second electrode; a second encapsulation layer disposed on the first encapsulation layer; and a third encapsulation layer disposed on the second encapsulation layer,
wherein the first encapsulation layer is in direct contact with the organic layer in the opening.

9. The display apparatus of claim 3, wherein the organic layer is in direct contact with the protective layer in the opening.

10. The display apparatus of claim 1, further comprising: a plurality of first circuit lines electrically connected to the thin film transistor and extending in a first direction; and a plurality of second circuit lines electrically connected to the thin film transistor and extending in a second direction intersecting the first direction,
wherein the plurality of first circuit lines are repeatedly disposed in the second direction, and the plurality of second circuit lines are repeatedly disposed in the first direction, and
wherein the transparent and magnetic close-contact member is disposed between a plurality of adjacent first circuit lines and between a plurality of adjacent second circuit lines.

11. The display apparatus of claim 1, wherein a light transmittance of the transmissive area is higher than a light transmittance of the non-transmissive area.

12. The display apparatus of claim 11, further comprising a normal area disposed around the optical area and having a higher pixels per inch (PPI) than the optical area.

13. The display apparatus of claim 1, wherein the transparent and magnetic close-contact member includes magnetite (Fe₃O₄).

14. The display apparatus of claim 1, further comprising an optical electronic device that is disposed to overlap the optical area and to receive external light.

15. A display apparatus, comprising:
a display area for displaying a screen;
a non-display area disposed outside the display area;
an optical area including a transmissive area and a non-transmissive area having different light transmittances;
a normal area having a higher pixels per inch (PPI) than the optical area;
a light-emitting part disposed across the non-transmissive area of the optical area and the normal area;
a transparent and magnetic close-contact member disposed in the transmissive area; and
an optical electronic device that is disposed to overlap the optical area and to receive external light.

16. The display apparatus of claim 15, further comprising:
a substrate in which the transmissive area and the non-transmissive area are defined;
a thin film transistor disposed on the substrate;
a protective layer disposed on the thin film transistor; and
a first electrode disposed on the protective layer,
wherein the transparent and magnetic close-contact member is disposed on the protective layer.

17. The display apparatus of claim 16, further comprising a bank disposed on the first electrode,
wherein the bank defines a light-emitting area passing through the bank in a thickness direction to expose the first electrode, and an opening passing through the bank in the thickness direction to expose at least one of the transparent and magnetic close-contact member and the protective layer.

18. The display apparatus of claim 17, wherein the light-emitting part is disposed in the non-transmissive area, and at least a part of the opening is disposed in the transmissive area.

19. The display apparatus of claim 16, wherein the first electrode and the transparent and magnetic close-contact member are disposed on a same layer.

20. The display apparatus of claim 15, further comprising:
a light-emitting part disposed in the display area;
a thin film transistor electrically connected to the light-emitting part in the display area;
a plurality of first circuit lines electrically connected to the thin film transistor and extending in a first direction; and
a plurality of second circuit lines electrically connected to the thin film transistor and extending in a second direction intersecting the first direction,
wherein the plurality of first circuit lines are repeatedly disposed in the second direction, and the plurality of second circuit lines are repeatedly disposed in the first direction, and
wherein the transparent and magnetic close-contact member is disposed between a plurality of adjacent first circuit lines and between a plurality of adjacent second circuit lines.
